(19) United States
(12) Patent Application Publication
(10) Pub. No.: US 2024/0315026 A1
(43) Pub. Date: Sep. 19, 2024

(54) SEMICONDUCTOR STORAGE DEVICE

(71) Applicant: Kioxia Corporation, Tokyo (JP)

(72) Inventors: Ayumi WATARAI, Ama (JP); Kenji TASHIRO, Kuwana (JP); Kosei NODA, Yokkaichi (JP)

(73) Assignee: Kioxia Corporation, Tokyo (JP)

(21) Appl. No.: 18/599,913

(22) Filed: Mar. 8, 2024

(30) Foreign Application Priority Data
Mar. 14, 2023 (JP) 2023-039579

(51) Int. Cl. H10B 43/27; H10B 41/27

(52) U.S. Cl. CPC H10B 43/27; H10B 41/27

(57) ABSTRACT

According to one embodiment, in a semiconductor storage device, a plurality of second pillars each includes a first sub-pillar that is a single substance of a first insulating layer extending in the stacking direction in a lower layer side of a stacked body and a second sub-pillar arranged at a height position in an upper layer side of the stacked body to correspond to the first sub-pillar. The second sub-pillar includes a semiconductor layer extending in the stacking direction at the height position in the upper layer side of the stacked body, a second insulating layer covering a sidewall of the semiconductor layer, a third insulating layer covering a sidewall of the second insulating layer, and a fourth insulating layer that includes a different material from the second and third insulating layers and is interposed between the second and third insulating layers.

### CROSS-REFERENCE TO RELATED APPLICATIONS

This application is based upon and claims the benefit of priority from Japanese Patent Application No. 2023-039579, filed on Mar. 14, 2023; the entire contents of which are incorporated herein by reference.

### FIELD

An embodiment described herein relates generally to a semiconductor storage device.

### BACKGROUND

In a semiconductor storage device such as a three-dimensional nonvolatile memory, a plurality of memory pillars is arranged to penetrate a stacked body in which a plurality of conductive layers and a plurality of insulating layers are alternately stacked. Furthermore, dummy pillars may be arranged to suppress the stacked body from sinking in the stacking direction in areas where no memory pillars are arranged. However, at this time, the dummy pillar and other components may interfere with each other, affecting the electrical characteristics of the semiconductor storage device.

### BRIEF DESCRIPTION OF THE DRAWINGS

FIG. 1 is a cross-sectional view illustrating a schematic configuration example of a semiconductor storage device according to an embodiment;

FIGS. 2A to 2E are diagrams illustrating an exemplary configuration of the semiconductor storage device according to the embodiment;

FIGS. 3A to 3C are diagrams illustrating an exemplary configuration of the semiconductor storage device according to the embodiment;

FIGS. 4A to 4E are diagrams sequentially illustrating a part of the procedure of a method of manufacturing the semiconductor storage device according to the embodiment;

FIGS. 5A to 5D are diagrams sequentially illustrating a part of the procedure of the method of manufacturing the semiconductor storage device according to the embodiment;

FIGS. 6A to 6C are diagrams sequentially illustrating a part of the procedure of the method of manufacturing the semiconductor storage device according to the embodiment;

FIGS. 7A and 7B are diagrams sequentially illustrating a part of the procedure of the method of manufacturing the semiconductor storage device according to the embodiment;

FIGS. 8A and 8B are diagrams sequentially illustrating a part of the procedure of the method of manufacturing the semiconductor storage device according to the embodiment;

FIGS. 9A to 9C are diagrams sequentially illustrating a part of the procedure of the method of manufacturing the semiconductor storage device according to the embodiment;

FIGS. 10A to 10C are diagrams sequentially illustrating a part of the procedure of the method of manufacturing the semiconductor storage device according to the embodiment;

FIG. 11 is a diagram sequentially illustrating a part of the procedure of the method of manufacturing the semiconductor storage device according to the embodiment;

FIG. 12 is a diagram sequentially illustrating a part of the procedure of the method of manufacturing the semiconductor storage device according to the embodiment;

FIGS. 13A and 13B are diagrams sequentially illustrating a part of the procedure of the method of manufacturing the semiconductor storage device according to the embodiment;

FIGS. 14A and 14B are diagrams sequentially illustrating a part of the procedure of the method of manufacturing the semiconductor storage device according to the embodiment;

FIGS. 15A and 15B are diagrams sequentially illustrating a part of the procedure of the method of manufacturing the semiconductor storage device according to the embodiment;

FIGS. 16A and 16B are diagrams sequentially illustrating a part of the procedure of the method of manufacturing the semiconductor storage device according to the embodiment;

FIGS. 17A and 17B are diagrams sequentially illustrating a part of the procedure of the method of manufacturing the semiconductor storage device according to the embodiment;

FIGS. 18A and 18B are diagrams sequentially illustrating a part of the procedure of the method of manufacturing the semiconductor storage device according to the embodiment;

FIGS. 19A to 19D are diagrams sequentially illustrating a part of the procedure of the method of manufacturing the semiconductor storage device according to the embodiment;

FIGS. 20A to 20C are diagrams sequentially illustrating a part of the procedure of the method of manufacturing the semiconductor storage device according to the embodiment;

FIGS. 21A to 21C are diagrams illustrating an exemplary configuration of a semiconductor storage device according to a first modification of the embodiment;

FIGS. 22A to 22C are diagrams illustrating an exemplary configuration of a semiconductor storage device according to a second modification of the embodiment;

FIGS. 23A to 23C are diagrams illustrating an exemplary configuration of a semiconductor storage device according to a third modification of the embodiment; and

FIGS. 24A to 24C are cross-sectional views along the X-direction illustrating a part of the procedure of a method of manufacturing the semiconductor storage device according to the third modification of the embodiment.

### DETAILED DESCRIPTION

In general, according to one embodiment, a semiconductor storage device includes a stacked body, a first pillar, and a plurality of second pillars. The stacked body includes a plurality of conductive layers stacked apart from each other. The plurality of conductive layers is processed into a step shape in a stepped portion. The first pillar extends in a stacking direction of the stacked body in the stacked body different from the stepped portion and forms a memory cell at each intersection portion with at least a part of the plurality of conductive layers. The plurality of second pillars extends in the stacking direction in the stepped portion. The plurality of second pillars each includes a first sub-pillar that is a single substance of a first insulating layer extending in the stacking direction in a lower layer side of the stacked body, and a second sub-pillar arranged at a height position in an upper layer side of the stacked body to correspond to the first sub-pillar. The second sub-pillar includes a semiconductor layer extending in the stacking direction at the height position in the upper layer side of the stacked body, a second insulating layer covering a sidewall of the semiconductor layer, a third insulating layer covering a sidewall of the second insulating layer, and a fourth insulating layer that includes a different material from the second and third insulating layers and is interposed between the second and third insulating layers.

Exemplary embodiments of the semiconductor storage device will be described below in detail with reference to the accompanying drawings. Note that, the present invention is not limited to the following embodiments. Furthermore, the constituent components in the embodiments described below include those that can be easily conceived by those skilled in the art or those that are substantially identical.

### (Exemplary Configuration of Semiconductor Storage Device)

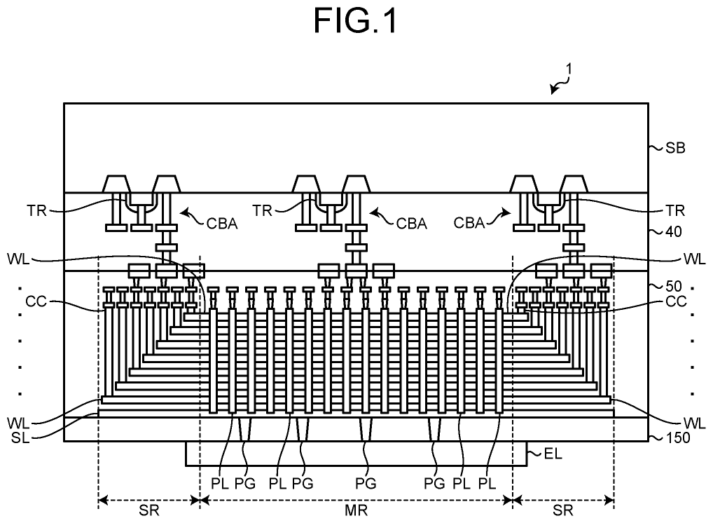

FIG. 1 is a cross-sectional view illustrating a schematic configuration example of a semiconductor storage device 1 according to an embodiment. However, in FIG. 1, hatching is omitted, considering the ease of viewing the drawing.

As illustrated in FIG. 1, the semiconductor storage device 1 includes, in order from the bottom of the page, an electrode film EL, a source line SL, and a plurality of word lines WL. Further, the semiconductor storage device 1 includes a peripheral circuit CBA provided on a semiconductor substrate SB above the plurality of word lines WL. Note that in the description of FIG. 1, the side on which the semiconductor substrate SB is arranged is assumed to be the upper side of the semiconductor storage device 1.

The source line SL is arranged on the electrode film EL with an insulating layer 150 interposed therebetween. A plurality of plugs PG is arranged in the insulating layer 150, and electrical continuity is maintained between the source line SL and the electrode film EL via the plugs PG. Although not illustrated, an electrode pad for supplying power and signals to the semiconductor storage device 1 from the outside is provided in the same layer as the electrode film EL.

The plurality of word lines WL is stacked above the source line SL. A memory region MR is arranged at the center of the plurality of word lines WL, and a step region SR is arranged at both ends of the plurality of word lines WL.

A plurality of pillars PL, which passes through the word lines WL in the stacking direction, is arranged in the memory region MR. A plurality of memory cells is formed at the intersection portions of the pillars PL and the word lines WL. This arrangement allows the semiconductor storage device 1 to be configured as a three-dimensional nonvolatile memory in which memory cells are arranged three-dimensionally in the memory region MR, for example.

In the step region SR, the plurality of word lines WL is processed into a step-like shape and terminates. Contacts CC connected to the word lines WL of each layer are arranged in the terrace portion of each level formed by the plurality of word lines WL.

These contacts CC allow the word lines WL stacked in multiple layers to be individually drawn out. From these contacts CC, write voltages, read voltages, or the like are applied to memory cells included in the memory region MR at the center of the plurality of word lines WL via the word lines WL located at the same level as the memory cells.

The plurality of word lines WL, the pillars PL, and the contacts CC are covered with an insulating layer 50. The insulating layer 50 also extends around the plurality of word lines WL.

The semiconductor substrate SB above the insulating layer 50 is, for example, a silicon substrate or the like. The peripheral circuit CBA including a transistor TR, wiring, or the like is arranged on the surface of the semiconductor substrate SB. Various voltages applied to the memory cells from the contacts CC are controlled by the peripheral circuit CBA electrically connected to these contacts CC. This arrangement enables the peripheral circuit CBA to control the electrical operation of the memory cell.

The peripheral circuit CBA is covered with an insulating layer 40, and bonding the insulating layer 40 to the insulating layer 50 covering the plurality of word lines WL or other components allows semiconductor storage device 1 to include the configuration provided with the plurality of word lines WL, the pillars PL, and the contacts CC and include the peripheral circuit CBA.

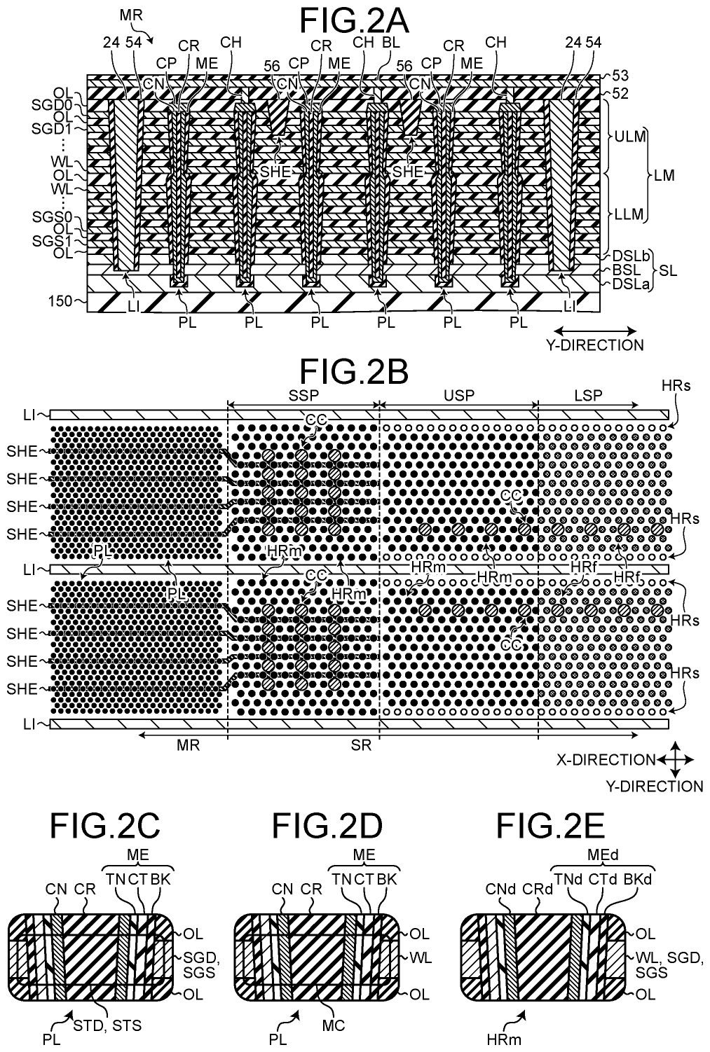

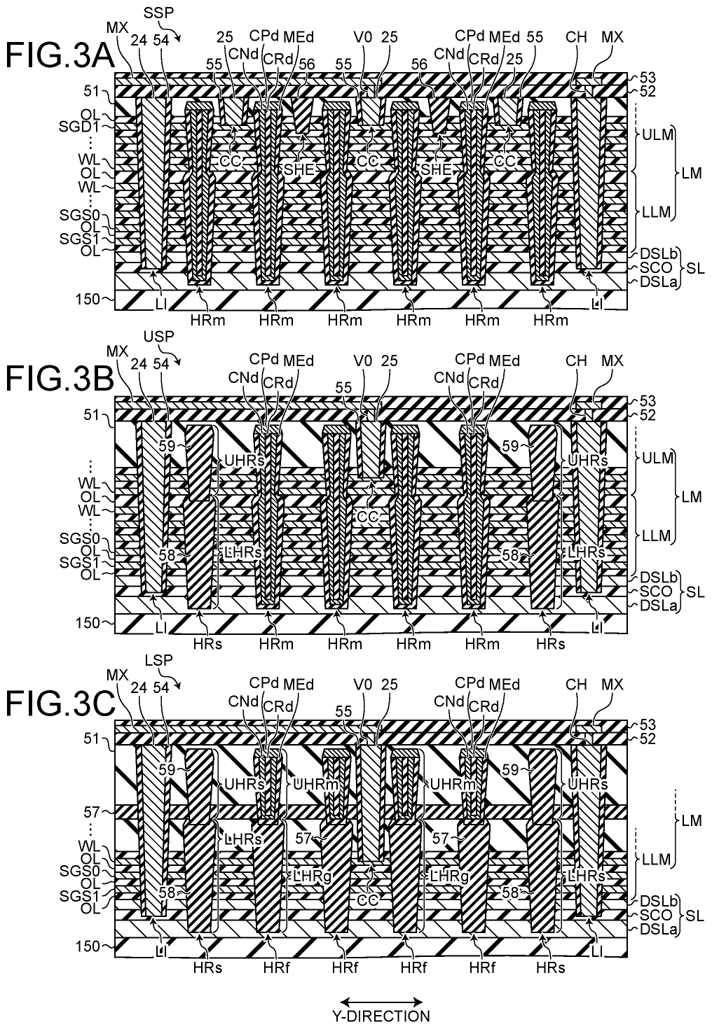

A detailed configuration example of the semiconductor storage device 1 is now described by referring to FIGS. 2A to 3C. FIGS. 2A to 3C are diagrams illustrating an exemplary configuration of the semiconductor storage device 1 according to the embodiment.

More specifically, FIG. 2A is a cross-sectional view along the Y-direction illustrating an exemplary configuration of the pillar PL. In FIG. 2A, the structure below the insulating layer 150 and above an insulating layer 53, which will be described later, is omitted.

FIG. 2B is an XY cross-sectional view of a partial region of a stacked body LM at the height position of a selection gate line SGD.

FIGS. 2C to 2E are respectively an enlarged sectional view of the pillar PL at the height position of the selection gate lines SGD or SGS, an enlarged sectional view of the pillar PL at the height position of the word line WL, and an enlarged cross-sectional view of a columnar portion HRm at the height position of the word line WL or the selection gate lines SGD or SGS.

FIG. 3A is a sectional view along the Y-direction illustrating an exemplary configuration of the columnar portion HRm, FIG. 3B is a sectional view along the Y-direction illustrating an exemplary configuration of the columnar portions HRm and HRs, and FIG. 3C is a sectional view along the Y-direction illustrating an exemplary configuration of the columnar portions HRf and HRs. In FIGS. 3A to 3C, the structures below the insulating layer 150 and above the insulating layer 53 are omitted.

Note that the diagrams illustrated in FIGS. 2A to 3C are only schematic diagrams, and the layouts of the parts illustrated in the cross-sectional views of FIGS. 2A and 3A to 3C and the XY cross-sectional view of FIG. 2B do not necessarily match.

Further, in this specification, both the X-direction and the Y-direction are directions along the direction of the plane of the word line WL, and the X-direction and the Y-direction are orthogonal to each other. In addition, the electrical draw-out direction of the word line WL may be referred to as a first direction, which is a direction along the X-direction. In addition, a direction intersecting the first direction may be referred to as a second direction, which is a direction along the Y-direction. However, the semiconductor storage device 1 may include manufacturing variations, so the first direction and the second direction are not necessarily orthogonal.

Further, herein, the direction in which the terrace surfaces of the word lines WL at each step in the step region SR face is defined as the upward direction.

As illustrated in FIG. 2A, the source line SL has a multilayer structure in which, for example, a lower source line DSLa, an intermediate source line BSL, and an upper source line DSLb are stacked in this order on the insulating layer 150. Here, the intermediate source line BSL is arranged below the memory region MR of the stacked body LM.

The lower source line DSLa, the intermediate source line BSL, and the upper source line DSLb are, for example, polysilicon layers. Among them, at least the intermediate source line BSL may be a conductive polysilicon layer or the like in which impurities are diffused.

The stacked body LM is arranged above the source line SL. The stacked body LM includes stacked bodies LLM and ULM in which the plurality of word lines WL and a plurality of insulating layers OL are alternately stacked one layer at a time.

The stacked body LLM is arranged above the source line SL. In a layer further below the lowermost word line WL of the stacked body LLM, a plurality of selection gate lines SGS0 and SGS1 is arranged in this order from the upper layer side of the stacked body LLM with the insulating layer OL interposed therebetween. The stacked body ULM is arranged on the stacked body LLM. In a layer further above the uppermost word line WL of the stacked body ULM, a plurality of selection gate lines SGD0 and SGD1 is arranged in this order from the upper layer side of the stacked body ULM with the insulating layer OL interposed therebetween.

However, the number of stacked layers of the word lines WL and selection gate lines SGD and SGS in the stacked body LM is optional. The word line WL and the selection gate lines SGD and SGS are made of, for example, a tungsten layer or a molybdenum layer. The insulating layer OL is, for example, a silicon oxide layer.

The upper surface of the stacked body LM is covered with an insulating layer 52. The insulating layer 52 is covered with an insulating layer 53. The insulating layers 52 and 53 each constitute a part of the insulating layer 50 in FIG. 1 together with an insulating layer 51 described later.

As illustrated in FIG. 2B, the word line WL and the selection gate lines SGD and SGS mentioned above are processed into a step-like shape, resulting in the step region SR having stepped portions SSP, USP, and LSP.

The stepped portion SSP is the uppermost layer portion of the stacked body LM, that is, a portion where the selection gate line SGD is processed into a step-like shape. The stepped portion USP is a portion of the upper layer of the stacked body LM excluding the selection gate line SGD, that is, a portion where the word line WL of the stacked body ULM is processed into a step-like shape. The stepped portion LSP is a lower portion of the stacked body LM, that is, a portion where the word line WL and the selection gate line SGS of the stacked body LLM are processed into a step-like shape.

The stepped portions SSP, USP, and LSP are arranged in the step region SR in this order to move away from the memory region MR. That is, as the distance from the memory area MR increases, the height positions of the terrace portions of the stepped portions SSP, USP, and LSP decrease.

As illustrated in FIGS. 2A and 2B, the stacked body LM is divided in the Y-direction by a plurality of plate-like contacts LI.

In other words, the respective plate-like contacts LI are aligned with each other in the Y-direction and extend in a direction along the stacking direction and the X-direction of the stacked body LM. In this way, the plate-like contact LI extends continuously within the stacked body LM from one end in the X-direction to the other end of the stacked body LM. In addition, the plate-like contact LI penetrates through the stacked body LM and the upper source line DSLb, and reaches the intermediate source line BSL in the memory region MR.

Further, the plate-like contact LI has a tapered shape, for example, such that the width in the Y-direction decreases from the upper end toward the lower end. Alternatively, the plate-like contact LI has a bowing shape in which the width in the Y-direction is maximum at a predetermined position between the upper end and the lower end, for example.

Each of the plate-like contacts LI includes an insulating layer 54 and a conductive layer 24. The insulating layer 54 is, for example, a silicon oxide layer. The conductive layer 24 is, for example, a tungsten layer or a conductive polysilicon layer.

The insulating layer 54 covers sidewalls of the plate-like contact LI that face each other in the Y-direction. The conductive layer 24 is filled inside the insulating layer 54 and is electrically connected to the source lines SL including the intermediate source line BSL. Furthermore, the conductive layer 24 is connected to the upper layer wiring in a cross section different from that in FIG. 2A. Such a configuration allows the plate-like contact LI to function as a source line contact.

However, instead of the plate-like contact LI, a plate-like member filled with an insulating layer may penetrate the stacked body LM and extend in the direction along the X-direction, dividing the stacked body LM in the Y-direction. In this case, such a plate-like member does not have a function as a source line contact.

Furthermore, in the memory region MR and the stepped portion SSP of the step region SR, a plurality of separation layers SHE is arranged between the plate-like contacts LI adjacent in the Y-direction. The separation layer SHE penetrates the upper layer portion of the stacked body ULM and extends in the direction along the X-direction. These separation layers SHE are insulating layers 56 such as silicon oxide layers that penetrate through the selection gate lines SGD0 and SGD1 and reach the insulating layer OL directly below the selection gate line SGD1.

In other words, these separation layers SHE penetrating the upper layer portion of the stacked body ULM extend the memory region MR and the stepped portion SSP in the X-direction between the plate-like contacts LI, enabling the upper layer portion of the stacked body ULM to be partitioned into selection gate lines SGD0 and SGD1 described above.

As illustrated in FIG. 2A, in the memory region MR, the plurality of pillars PL, which penetrates the stacked body LM, the upper source line DSLb, and the intermediate source line BSL to reach the lower source line DSLa, is distributed and arranged.

The plurality of pillars PL is arranged, for example, in a staggered form when viewed from the stacking direction of the stacked body LM. Each pillar PL has, for example, a circular shape, an elliptical shape, an oval shape, or the like as a cross-sectional shape in a direction along the layer direction of the stacked body LM, that is, in a direction along the XY plane.

Further, the pillar PL has a tapered shape in which the diameter and cross-sectional area become smaller from the upper layer side to the lower layer side in the portion penetrating the stacked body LLM and the portion penetrating the stacked body ULM. Alternatively, each pillar PL has a bowing shape in which the diameter and cross-sectional area are maximum at a predetermined position between the upper layer side and the lower layer side in the portion penetrating the stacked body LLM and the portion penetrating the stacked body ULM.

Each of the plurality of pillars PL includes a memory layer ME extending in the stacking direction within the stacked body LM, a channel layer CN penetrating through the stacked body LM and connected to the intermediate source line BSL, a cap layer CP covering the upper surface of the channel layer CN, and a core layer CR that is a core material of the pillar PL.

As illustrated in FIGS. 2C and 2D, the memory layer ME has a multilayer structure in which a block insulating layer BK, a charge storage layer CT, and a tunnel insulating layer TN are stacked in this order from the outer peripheral side of the pillar PL. More specifically, the memory layer ME is arranged on the side surface of the pillar PL except for the depth position of the intermediate source line BSL. Furthermore, the memory layer ME is also arranged on the bottom surface of the pillar PL that reaches the depth of the lower source line DSLa.

The channel layer CN penetrates the stacked body LM, the upper source line DSLb, and the intermediate source line BSL inside the memory layer ME, and reaches the depth of the lower source line DSLa. More specifically, the channel layer CN is arranged on the side and bottom surfaces of the pillar PL together with the memory layer ME on an outermost side. However, a part of the channel layer CN is disposed on the outermost side of the pillar PL to be exposed from the memory layer ME and in contact with the intermediate source line BSL on the side surface, being electrically connected to the source line SL including the intermediate source line BSL. The core layer CR is filled further inside the channel layer CN.

Further, each of the plurality of pillars PL has the cap layer CP at the upper end portion. The cap layer CP is arranged at the upper end of the pillar PL to cover at least the upper end of the channel layer CN, and is connected to the channel layer CN. The cap layer CP is connected to a bit line BL arranged in the insulating layer 53 via a plug CH arranged in the insulating layer 52. The bit line BL extends above the stacked body LM in a direction along the Y-direction to intersect with the direction in which the word line WL is drawn out.

Note that in FIG. 2A, the plug CH is connected to only three pillars PL out of six pillars PL. The other pillars PL are connected to other bit lines BL that extend in the Y-direction in parallel with the bit lines BL illustrated in FIG. 2A at positions different from the cross section illustrated in FIG. 2A via the plug CH that is not illustrated in FIG. 2A.

The block insulating layer BK and the tunnel insulating layer TN of the memory layer ME, and the core layer CR are, for example, silicon oxide layers. The charge storage layer CT of the memory layer ME is, for example, a silicon nitride layer. The channel layer CN and the cap layer CP are semiconductor layers such as polysilicon layers or amorphous silicon layers, for example.

As illustrated in FIG. 2D, the configuration described above allows the memory cells MC to be formed in the portions of the side surfaces of the pillars PL that face the respective word lines WL. Applying a predetermined voltage from the word line WL enables data to be written to and read from the memory cell MC.

Furthermore, as illustrated in FIG. 2C, a selection gate STD is formed in each of the portions where the side surfaces of the pillar PL face the selection gate lines SGD0 and SGD1 arranged above the word lines WL. In addition, a selection gate STS is formed in each of the portions where the side surfaces of the pillar PL face the selection gate lines SGS0 and SGS1 arranged below the word lines WL.

Applying a predetermined voltage from the selection gate lines SGD and SGS allows the selection gates STD and STS to be turned on or off, and the memory cells MC of the pillars PL to which the selection gates STD and STS belong to be selected or unselected state.

As illustrated in FIGS. 3A to 3C, in the step region SR, the stepped portions SSP, USP, and LSP are covered with the insulating layer 51. The insulating layer 51 reaches, for example, the height position of the uppermost layer of the stacked body LM, and the insulating layers 52 and 53 also cover the upper surface of the insulating layer 51. As mentioned above, the insulating layer 51 also constitutes a portion of the insulating layer 50 in FIG. 1.

The insulating layer 51 is dTEOS (densified TEOS) layer formed by plasma chemical vapor deposition (CVD) or the like using, for example, the Tetra Ethyl Ortho Silicate (TEOS) as a raw material.

Further, in the step region SR, the source line SL includes an intermediate insulating layer SCO interposed between the upper source line DSLb and the lower source line DSLa instead of the intermediate source line BSL interposed therebetween. The intermediate insulating layer SCO is, for example, a silicon oxide layer.

For this reason, in the step region SR, the plate-like contact LI penetrates through the insulating layer 51, the stacked body LM, and the upper source line DSLb, reaching the intermediate insulating layer SCO. In addition, the upper end portion of the plate-like contact LI is connected to an upper layer wiring MX arranged in the insulating layer 53 via the plug CH arranged in the insulating layer 52.

Further, in the step region SR, the contact CC and the plurality of columnar portions HRm, HRs, and HRf are arranged. As will be described later, these columnar portions HRm, HRs, and HRf have the role of supporting the structure of the stacked body LM upon forming the stacked body LM from a stacked body in which a sacrificial layer and an insulating layer are stacked and do not contribute to the function of the semiconductor storage device 1.

Each contact CC penetrates the insulating layer 51 and is connected to the word line WL or the selection gate line SGD or SGS directly below the insulating layer OL forming each step of the stepped portions SSP, USP, and LSP.

Each contact CC has, for example, a tapered shape in which the diameter and cross-sectional area become smaller from the upper end toward the lower end. Alternatively, the contact CC has a bowing shape in which the diameter and cross-sectional area are maximum at a predetermined position between the upper end and the lower end, for example.

Further, the contact CC includes an insulating layer 55 that covers the outer periphery of the contact CC and includes a conductive layer 25 such as a tungsten layer or a copper layer that is filled inside the insulating layer 55. The conductive layer 25 is connected to the upper layer wiring MX arranged in the insulating layer 53 via a plug V0 arranged in the insulating layer 52. This upper layer wiring MX is electrically connected to the above-mentioned peripheral circuit CBA (see FIG. 1).

Such a configuration enables each layer of the word line WL and the selection gate lines SGD and SGS in the layers above and below the word line WL to be electrically drawn out. That is, the configuration described above makes it possible to apply a predetermined voltage from the peripheral circuit CBA to the memory cell MC via the upper layer wiring MX, the contact CC, the word line WL, or the like to operate the memory cell MC as a memory element.

As illustrated in FIG. 3A, the stepped portion SSP is a portion where each pair of selection gate line SGD and the insulating layer OL is processed into a step-like shape. In the stepped portion SSP, the plurality of columnar portions HRm, which penetrates the insulating layer 51, the stacked bodies ULM and LLM, the upper source line DSLb, and the intermediate insulating layer SCO to reach the lower source line DSLa, is distributed and arranged.

The plurality of columnar portions HRm is arranged, for example, in a grid-like or staggered form when viewed from the stacking direction of the stacked body LM, while avoiding interference with the plate-like contacts LI and the contacts CC. Each columnar portion HRm has, for example, a circular shape, an elliptical shape, an oval shape, or the like as a cross-sectional shape in the direction along the XY plane.

Further, each of the columnar portions HRm has a tapered shape in which the diameter and cross-sectional area decrease from the upper layer side to the lower layer side in the portion penetrating the stacked body LLM and the portion penetrating the stacked body ULM. Alternatively, each of the columnar portions HRm has a bowing shape in which the diameter and cross-sectional area are maximum at a predetermined position between the upper layer side and the lower layer side in the portion penetrating the stacked body LLM and the portion penetrating the stacked body ULM.

Each of the plurality of columnar portions HRm has a layer structure identical to that of the pillar PL described above. However, the plurality of columnar portions HRm is in a floating state as a whole and, as described above, has no electrical function in the semiconductor storage device 1.

Further, arranging the columnar portion HRm while avoiding interference with the plate-like contacts LI and the contacts CC as described above suppresses the influence caused by contact between the columnar portion HRm, having a layer structure similar to the pillar PL, and the plate-like contacts LI and the contacts CC.

As a layer structure identical to that of the pillar PL, the columnar portion HRm has dummy layers MEd, CNd, and CRd extending in the stacking direction within the stacked body LM.

As illustrated in FIG. 2E, the dummy layer MEd has a multilayer structure in which dummy layers BKd, CTd, and TNd are stacked in this order from the outer peripheral side of the columnar portion HRm. In other words, the dummy layer MEd corresponds to the memory layer ME of the pillar PL described above. In addition, the dummy layers BKd, CTd, and TNd included in the dummy layer MEd correspond to the block insulating layer BK, the charge storage layer CT, and the tunnel insulating layer TN of the pillar PL, respectively.

However, the dummy layer MEd is arranged seamlessly on the side surface of the columnar portion HRm extending from the upper source line DSLb to the lower source line DSLa. The dummy layer MEd is also arranged at the lower end of the columnar portion HRm.

The dummy layer CNd penetrates the stacked body LM, the upper source line DSLb, and the intermediate insulating layer SCO inside the dummy layer MEd, and reaches the depth of the lower source line DSLa. The dummy layer CNd corresponds to the channel layer CN of the pillar PL described above.

However, the dummy layer MEd is arranged on the side surface of the dummy layer CNd from the upper source line DSLb to the lower source line DSLa, and the dummy layer CNd is not in direct contact with the intermediate insulating layer SCO. A dummy layer CRd is filled further inside the dummy layer CNd. The dummy layer CRd corresponds to the core layer CR of the pillar PL described above.

Further, each of the plurality of columnar portions HRm has a dummy layer CPd at its upper end. The dummy layer CPd is arranged at the upper end of the columnar portion HRm to cover at least the upper end of the dummy layer CNd, and is connected to the dummy layer CNd. The dummy layer CPd corresponds to the cap layer CP of the pillar PL described above. However, the columnar portion HRm does not need to have the dummy layer CPd.

The respective layers included in the columnar portion HRm include a similar kind of material to the corresponding layers of the pillar PL. That is, the dummy layers BKd, TNd of the dummy layer MEd, and the dummy layer CRd are, for example, silicon oxide layers. The dummy layer CTd is, for example, a silicon nitride layer. The dummy layers CNd and CPd are semiconductor layers such as polysilicon layers or amorphous silicon layers, for example. Herein, the semiconductor layer included in the dummy layer CNd and the like has a higher Young's modulus than, for example, the materials included in the other dummy layers MEd and CRd, and is hard and difficult to deform.

As illustrated in FIG. 3B, the stepped portion USP is a portion in which each pair of the word line WL and the insulating layer OL is processed into a step-like shape. In the stepped portion USP, the columnar portions HRm and HRs that penetrate the insulating layer 51, the stacked bodies ULM and LLM, the upper source line DSLb, and the intermediate insulating layer SCO to reach the lower source line DSLa are arranged.

In the stepped portion USP, the columnar portions HRs are arrayed in the direction along the X-direction on both sides of the plate-like contact LI in the Y-direction and adjacent to the plate-like contact LI in the Y-direction. Each columnar portion HRs has, for example, a circular shape, an elliptical shape, an oval shape, or the like as a cross-sectional shape in the direction along the XY plane.

Further, each of the columnar portions HRs has the columnar portion LHRs that penetrates the stacked body LLM from the upper end of the stacked body LLM to reach the source line SL, and the columnar portion UHRs that penetrates the stacked body ULM from the height position of the upper end of the stacked body ULM to be connected to the upper end of the columnar portion LHRs.

Each of the columnar portions LHRs and UHRs has a tapered shape, for example, with the diameter and cross-sectional area decreasing from the upper end toward the lower end. Alternatively, each of the columnar portions LHRs and UHRs has a bowing shape in which the diameter and cross-sectional area are maximum at a predetermined position, for example, between the upper end and the lower end.

Further, the columnar portions LHRs and UHRs are each individual entities of insulating layers 58 and 59 such as a silicon oxide layer. Thus, the columnar portion HRs has no electrical influence on other components, so interference with the adjacent plate-like contact LI is allowed. In addition, both the columnar portions LHRs and UHRs have a single-substance structure of the insulating layers 58 and 59 made of identical material, so these columnar portions LHRs and UHRs may not have an interface or the like at their boundary, sometimes making it difficult to distinguish them from each other.

In the stepped portion USP, the plurality of columnar portions HRm is distributed throughout the stepped portion USP except for the position adjacent to the plate-like contact LI. In the stepped portion USP, the columnar portion HRs is arranged adjacent to the plate-like contact LI in place of the columnar portion HRm for the following reason.

In the plate-like contact LI, the portion arranged in the insulating layer 51 tends to have a greater degree of tapered shape or bowing shape than the portion arranged in the stacked body LM. That is, in the case where the plate-like contact LI has a tapered shape, the difference between the width of the upper end and the width of the lower end of the plate-like contact LI is likely to become large in the insulating layer 51. In the case where the plate-like contact LI has a bowing shape, the difference between the maximum width of the plate-like contact LI and the width of the upper and lower ends of the plate-like contact LI is likely to become large in the insulating layer 51.

Further, the longer the distance extended in the insulating layer 51 in the stacking direction of the stacked body LM, the greater the degree of tapered or bowing shape of the plate-like contact LI is likely to become. That is, in the step region SR, the tapered or bowing shape of the plate-like contact LI is likely to become more noticeable in the region where the lower layers of the stacked body LM are processed into a step shape than in the region where the upper layers of the stacked body LM are processed into a step shape.

As described above, in the stepped portion USP where the maximum width of the plate-like contact LI tends to increase, the columnar portion HRm is not arranged adjacent to the plate-like contact LI, so interference with the plate-like contact LI is suppressed. In addition, in the stepped portion USP as well, the columnar portion HRm is arranged while avoiding interference with the contact CC.

As illustrated in FIG. 3C, the stepped portion LSP is a portion where each pair of the word line WL and the insulating layer OL or each pair of the selection gate line SGS and the insulating layer OL is processed into a step shape. In the stepped portion LSP, the columnar portions HRf and HRs that penetrate the insulating layer 51, the stacked body LLM, the upper source line DSLb, and the intermediate insulating layer SCO to reach the lower source line DSLa are arranged.

Further, in the insulating layer 51 covering the stepped portion LSP, between the portion disposed at the height position of the stacked body ULM and the portion disposed at the height position of the stacked body LLM, an insulating layer 57 such as a silicon oxide layer made of the material identical to that of a columnar portion LHRg, which is the lower structure of the columnar portion HRf described in detail below, is interposed. In addition, the insulating layer 57 extends in the direction along the XY plane and intersects with the columnar portions HRf and HRs that penetrate the insulating layer 51. The insulating layer 57 in the insulating layer 51 is formed in parallel with the formation of the columnar portion LHRg included in the columnar portion HRf, as described later.

The insulating layer 57 interposed in the insulating layer 51 and the insulating layer 51 are both made of the same material such as a silicon oxide layer. However, the insulating layer 51 is, as described above, a denser silicon oxide layer, such as a dTEOS layer. Thus, it is considered that, for example, the presence of the insulating layer 57 in the insulating layer 51 can be determined using SEM or the like.

The columnar portions HRs are also arrayed in the direction along the X-direction in the stepped portion LSP on both sides of the plate-like contact LI in the Y-direction and adjacent to the plate-like contact LI in the Y-direction. This is because in the stepped portion LSP, the width of the plate-like contact LI increases further, and the risk of contact with the plate-like contact LI further increases.

The plurality of columnar portions HRf is arranged, for example, in a grid-like or staggered form when viewed from the stacking direction of the stacked body LM, while avoiding interference with the plate-like contacts LI and contacts CC.

The columnar portions HRf each include the columnar portion LHRg that extends from the height position of the upper end of the stacked body LLM to reach the source line SL through the stacked body LLM. The columnar portions HRf each include a columnar portion UHRm that extends from the height position of the upper end of the stacked body ULM in the stacking direction and is connected to the upper end of the columnar portion LHRg.

In other words, the columnar portion HRf includes, as a lower structure, the columnar portion LHRg having the shape and layer structure identical to those of the lower structure of the above-described columnar portion HRs, for example. In addition, the columnar portion HRf includes, as an upper structure, the columnar portion UHRm having the shape and layer structure identical to those of the upper structure of the above-described columnar portion HRm, for example.

The plurality of columnar portions HRf is distributed over the entire stepped portion LSP except for the position adjacent to the plate-like contact LI in the stepped portion LSP. In this way, the columnar portion HRf is not arranged adjacent to the plate-like contact LI, so interference with the plate-like contact LI is suppressed.

Further, as described above, the arrangement of the upper end portion of the columnar portion HRf is determined to avoid interference with the contact CC, in principle. However, the columnar portion LHRg has a single-substance structure of the insulating layer 57, so interference with the contact CC is allowed in the lower structure of the columnar portion HRf. The reason why the columnar portion HRf has such a configuration is as follows.

The columnar portion HRf extends long in the stacking direction. Similarly, the contacts CC arranged in the stepped portion LSP also extend long in the stacking direction to connect to each layer of the stacked body LLM, which is the lower layer portion of the stacked body LM. Thus, at least one of the columnar portion HRf and the contact CC may be misaligned or be tilted due to stress or the like from other layers. For this reason, the columnar portion HRf has a structure that assumes the possibility of interference with the contact CC in the lower structure of the columnar portion HRf.

As described above, in the lower stepped portions USP and LSP of the step region SR, the columnar portions HRs, which are the insulating layers 58 and 59, are arranged near the plate-like contacts LI and are configured by assuming the possibility of occurrence of interference with the plate-like contacts LI. Furthermore, in the stepped portion LSP, the columnar portions HRf of which the lower structures are allowed to interfere with the contacts CC, are distributed and arranged.

On the other hand, in the stepped portion SSP of the uppermost layer of the stacked body LM, it is easy to suppress interference with the plate-like contact LI and the contact CC, so the columnar portions HRm, which have the same layer structure as the pillar PL and include the dummy layer CNd of a semiconductor layer with a high Young's modulus throughout the stacking direction, are distributed over the entire stepped portion SSP including the vicinity of the plate contact LI.

Note that at the identical height position in the stacked body LM, the cross-sectional area of the columnar portions HRm, HRs, and HRf in the direction along the XY plane is larger than, for example, the cross-sectional area of the pillar PL in the direction along the XY plane. In addition, the pitch between the plurality of columnar portions HRm, the pitch between the plurality of columnar portions HRs, and the pitch between the plurality of columnar portions HRf are, for example, larger than the pitch between the plurality of pillars PL. The arrangement density of the columnar portions HRm, HRs, and HRf per unit area of the word line WL in the stacked body LM is lower than the arrangement density of the pillars PL per unit area of the word line WL.

In this way, for example, configuring the cross-sectional area of the pillar PL to be smaller than that of the columnar portions HRm, HRs, and HRf and making the pitch narrow make it possible for a large number of memory cells MC to be densely formed in the stacked body LM of a predetermined size. The storage capacity of the semiconductor storage device 1 can be increased. On the other hand, the columnar portions HRm, HRs, and HRf are used exclusively to support the stacked body LM, it is possible to reduce the manufacturing load by not having a precise structure with a small cross-sectional area and a narrow pitch like the pillar PL, for example.

### (Method of Manufacturing Semiconductor Storage Device)

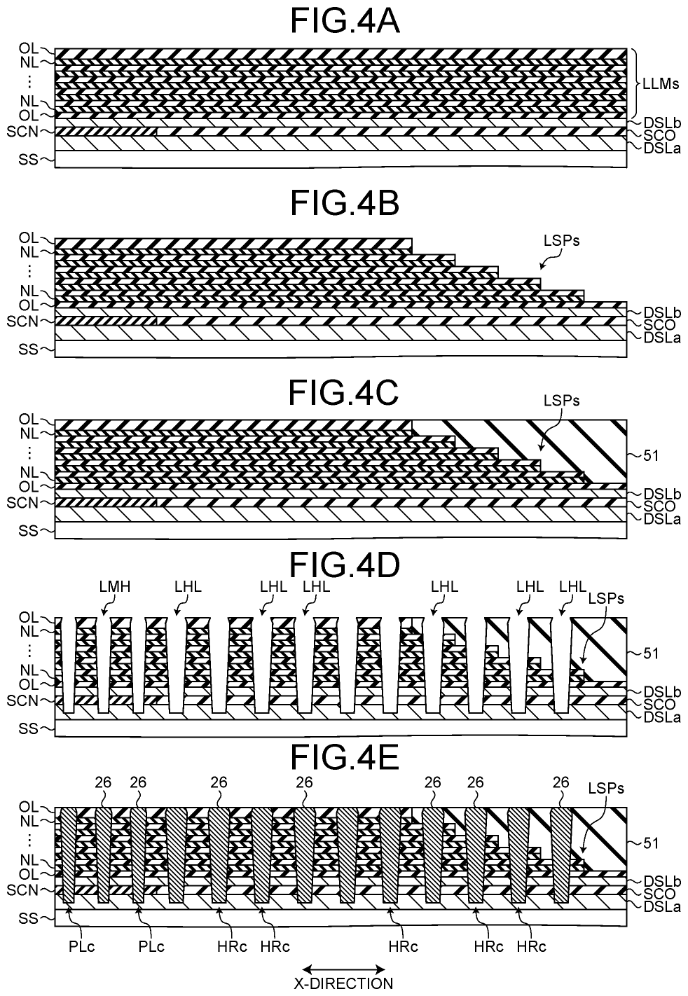

A method of manufacturing the semiconductor storage device 1 according to the embodiment is now described by reference to FIGS. 4A to 20C. FIGS. 4A to 20C are diagrams sequentially illustrating a part of the procedure of the method of manufacturing the semiconductor storage device 1 according to the embodiment.

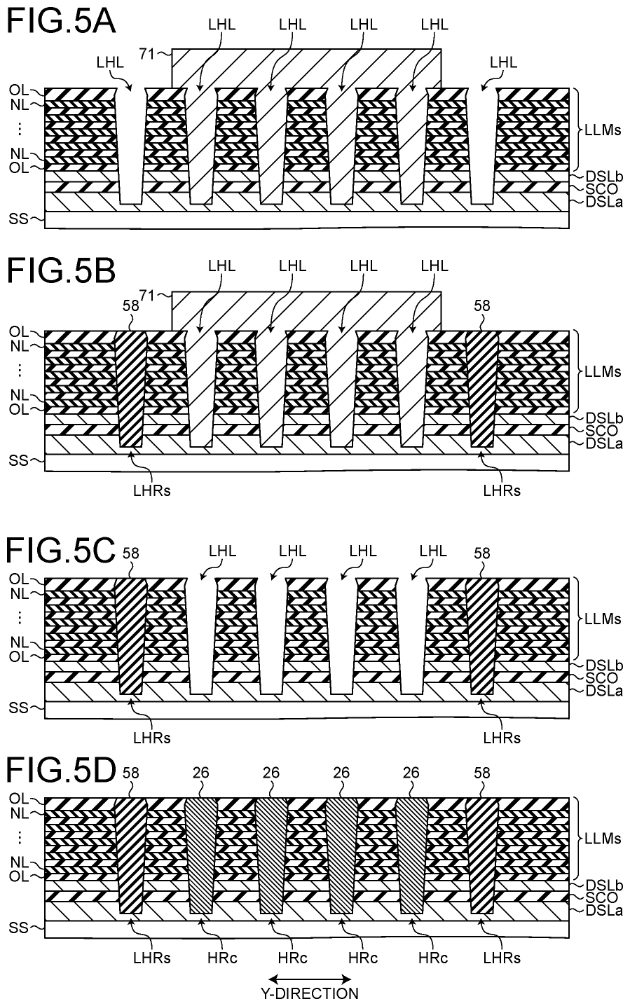

First, FIGS. 4A to 5D illustrate a stacked body LLMs, which is the lower layer portion of the stacked body LM before the word line WL is formed, and how various configurations are formed on the stacked body LLMs.

FIGS. 4A to 4E are cross-sectional views along the X-direction of regions that will later become the memory region MR and the step region SR.

As illustrated in FIG. 4A, the lower source line DSLa, the intermediate sacrificial layer SCN or the intermediate insulating layer SCO, and the upper source line DSLb are formed in this order on a support substrate SS.

As the support substrate SS, a semiconductor substrate such as a silicon substrate, an insulating substrate such as a ceramic substrate or an alumina substrate, a conductive substrate, or the like is usable. The insulating layer 150 can be formed on the upper surface side of the support substrate SS.

The intermediate sacrificial layer SCN is formed in a region on the support substrate SS that will later become the memory region MR, and the intermediate insulating layer SCO is formed in a region on the support substrate SS that will later become the step region SR. The intermediate sacrificial layer SCN is, for example, a silicon nitride layer or the like, and is a layer that will later be replaced with a polysilicon layer or the like to become the intermediate source line BSL. As described above, the intermediate insulating layer SCO is, for example, a silicon oxide layer or the like.

Further, the stacked body LLMs in which a plurality of insulating layers NL and the plurality of insulating layers OL are alternately stacked one layer at a time is formed on the upper source line DSLb. The insulating layer NL is, for example, a silicon nitride layer, and functions as a sacrificial layer that is later replaced with a conductive material and becomes the word line WL or the selection gate line SGS.

As illustrated in FIG. 4B, in a partial region of the stacked body LLMs, the insulating layer NL and the insulating layer OL are processed into a step shape to form a stepped portion LSPs. The stepped portion LSPs is formed by repeating slimming of a mask pattern such as a photoresist layer and etching of the insulating layer NL and the insulating layer OL of the stacked body LLMs multiple times.

In other words, a mask pattern is formed on the upper surface of the stacked body LLMs, and, for example, the exposed portions of the insulating layer NL and the insulating layer OL are etched away one layer at a time. In addition, by treatment using oxygen plasma or the like, the end portion of the mask pattern retreats to newly expose the upper surface of the stacked body LLMs, and the insulating layer NL and the insulating layer OL are further etched away one layer at a time. Repeating such processing multiple times forms the stepped portion LSPs.

As illustrated in FIG. 4C, the insulating layer 51 is formed to cover the stepped portion LSPs and reaches the height of the upper surface of the stacked body LLMs. The insulating layer 51 is also formed in the outer region of the stepped portion LSPs. As described above, the insulating layer 51 is obtained by forming a dTEOS layer using plasma CVD or the like.

As illustrated in FIG. 4D, a plurality of memory holes LMH and a plurality of holes LHL extending in the stacking direction of the stacked body LLMs are formed, for example, simultaneously. The memory hole LMH is a portion that will later become the lower structure of the pillar PL. The hole LHL is a portion that will later become the lower structure of any of the columnar portions HRm, HRS, and HRf.

The plurality of memory holes LMH is arranged in a region that will later become the memory region MR, penetrates the stacked body LLMs, the upper source line DSLb, and the intermediate sacrificial layer SCN, and reaches the lower source line DSLa. The plurality of holes LHL is arranged in a region that will later become the step region SR, penetrates the insulating layer 51, the stacked body LLMs, the upper source line DSLb, and the intermediate insulating layer SCO, and reaches the lower source line DSLa.

As illustrated in FIG. 4E, these memory holes LMH and holes LHL are filled with a sacrificial layer 26 such as a CVD-carbon layer. In this case, the sacrificial layer 26 is also formed on the upper surface of the stacked body LLMs. The sacrificial layer 26 on the upper surface is removed by, for example, etching back the entire surface.

As a result, pillars PLc in which the multiple memory holes LMH are filled with the sacrificial layer 26 are formed in a region that will later become the memory region MR. In addition, in a region that will later become the step region SR, columnar portions HRc are formed in which a plurality of holes LHL is filled with the sacrificial layer 26.

Moreover, more detailed processing steps of FIGS. 4D and 4E described above are illustrated in FIGS. 5A to 5D. FIGS. 5A to 5D are cross-sectional views along the Y-direction of a region that will later become the stepped portion USP of the step region SR.

As illustrated in FIG. 5A, among the plurality of holes LHL formed in the processing of FIG. 4D described above, some of the holes LHL in a region that will later become the stepped portion USP of the step region SR are covered with a mask layer 71 such as a photoresist layer.

More specifically, among the plurality of holes LHL illustrated in FIG. 5A, the holes LHL at both ends in the left-right direction of the drawing are adjacent to a portion where the plate-like contact LI will be formed later, and are arranged at a position where the columnar portion HRs will be formed. The plurality of holes LHL, except for the holes LHL at both ends in the left-right direction of the drawing, is covered with the mask layer 71 as described above.

As illustrated in FIG. 5B, the holes LHL at both left and right ends exposed from the mask layer 71 are filled with the insulating layer 58 to form the columnar portions LHRs. The insulating layer 58 is a silicon oxide layer or the like having a relatively low density compared to the insulating layer 51 which is the above-mentioned dTEOS layer or the like.

In this case, the insulating layer 58 is also formed on the upper surface of the stacked body LLMs. The insulating layer 58 on the upper surface of the stacked body LLMs is preferably removed using, for example, chemical mechanical polishing (CMP) or the like.

As illustrated in FIG. 5C, the mask layer 71 is removed using oxygen plasma or the like. As a result, a plurality of holes LHL is opened again in the center portion sandwiched between the columnar portions LHRs at both left and right ends.

The processing illustrated in FIG. 5D corresponds to the processing illustrated in FIG. 4E described above. That is, as illustrated in FIG. 5D, the sacrificial layer 26 is filled in the plurality of holes LHL that is opened again.

Moreover, the processing steps illustrated in FIGS. 5A to 5D are not performed in the region that will later become the stepped portion SSP. The processing steps described above can be performed on the already formed stepped portion LSPs in parallel with the region illustrated in FIGS. 5A to 5D that will later become the stepped portion USP.

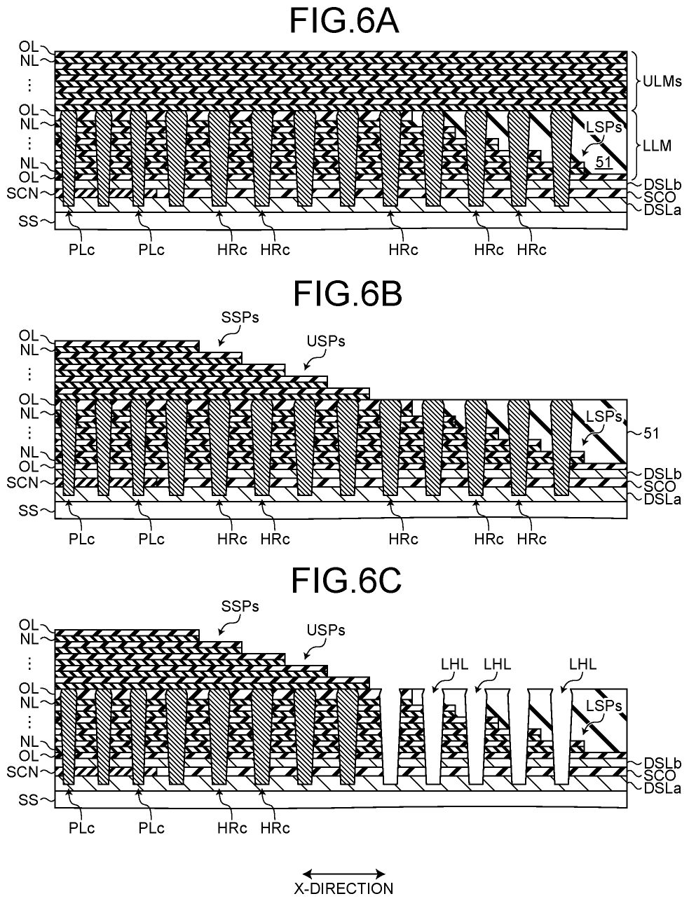

Then, FIGS. 6A to 10C illustrate how the stacked body ULMs, which is the upper layer portion of the stacked body LM before the word line WL is formed, is formed, and furthermore, the columnar portions HRs are formed in the stacked body LLMs and ULMs.

FIGS. 6A to 6C are cross-sectional views along the X-direction of regions that will later become the memory region MR and the step region SR, which is similar to FIGS. 4A to 4E described above.

As illustrated in FIG. 6A, the stacked body ULMs is formed. the stacked body ULMs covers the stacked body LLMs and the insulating layer 51 covering the stepped portion LSPs and has the plurality of insulating layers NL and the plurality of insulating layers OL alternately stacked one layer at a time. The sacrificial layer NL of the stacked body ULMs is later replaced with a conductive layer and becomes the word line WL or the selection gate line SGD.

As illustrated in FIG. 6B, in a partial region of the stacked body ULMs, the insulating layer NL and the insulating layer OL are processed into a step shape to form the stepped portions USPs and SSPs. The stepped portions USPs and SSPs are formed by repeating multiple times the slimming of a mask pattern such as a photoresist layer and the etching of the insulating layer NL and insulating layer OL of the stacked body ULMs, similar to the processing illustrated in FIG. 4B described above.

In this case, the top step of the stepped portion LSPs and the bottom step of the stepped portion USPs are brought close to each other to form the stepped portion USPs. This allows the stepped portions LSPs, USPs, and SSPs to be arranged to be continuous from the lower layer side to the upper layer side of the stacked bodies LLMs and ULMs. In addition, upon removal of the stacked body ULSMs on the insulating layer 51 covering the stepped portion LSPs, the upper end portion of the columnar portion HRC formed in the stepped portion LSPs is exposed on the upper surface of the insulating layer 51.

As illustrated in FIG. 6C, the sacrificial layer 26 filled in the columnar portion HRc is removed from the columnar portion HRc having the upper end exposed on the upper surface of the insulating layer 51 by ashing using oxygen plasma or the like. As a result, the hole LHL opens again in the stepped portion LSPs.

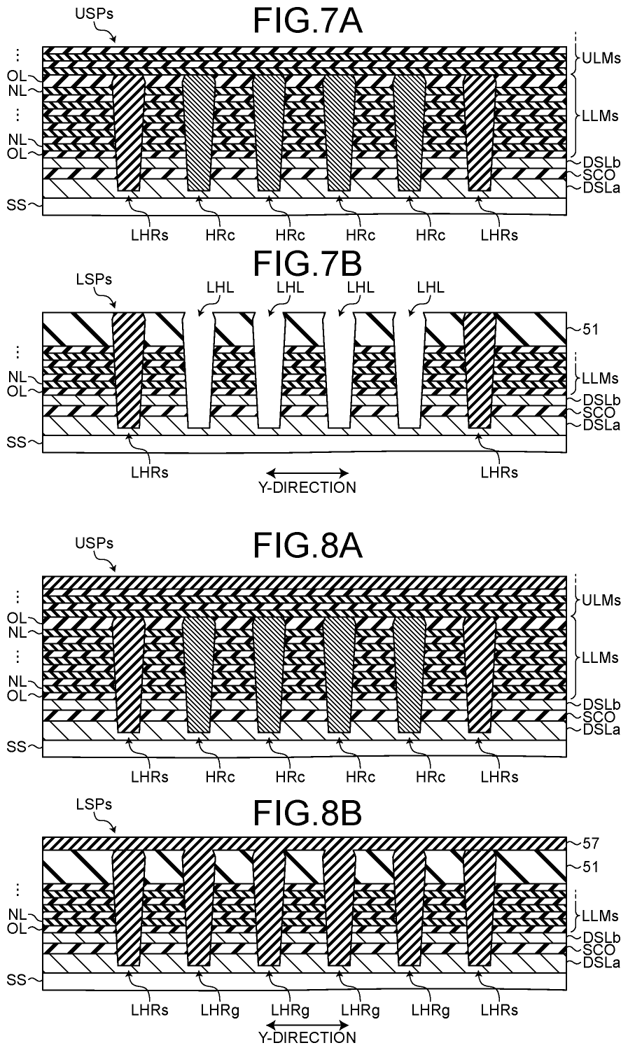

FIGS. 7A to 8B are cross-sectional views along the Y-direction of a region that will later become the step region SR. More specifically, FIGS. 7A and 8A are cross-sectional views of the stepped portion USPs, similar to FIGS. 5A to 5D described above, and FIGS. 7B and 8B are cross-sectional views of the stepped portion LSPs.

As illustrated in FIG. 7B, in the stepped portion LSPs, the hole LHL from which the sacrificial layer 26 is removed is opened, as described above. However, in the processing illustrated in FIGS. 5A to 5D described above, upon forming the columnar portion LHRs, which will later become the lower structure of the columnar portion HRs, in the stepped portion USPs, because similar processing has been performed to the stepped portion LSPs, the holes LHL at both ends in the left-right direction in the drawing have already been filled with the insulating layer 58 and the columnar portions LHRs have been formed.

As illustrated in FIG. 7A, in the stepped portion USPs, the upper ends of the plurality of columnar portions HRc are covered with the stacked body ULMs, so they are not subjected to the ashing processing illustrated in FIG. 6C described above. Similarly, even in the stepped portion SSPs, the sacrificial layer 26 is not removed, and a plurality of columnar portions HRc remains.

As illustrated in FIGS. 8A and 8B, the plurality of holes LHL opening in the stepped portion LSPs is filled with an insulating layer 57 in a similar manner to the processing of FIG. 5C described above. The insulating layer 57 is also a silicon oxide layer or the like having a lower density than the insulating layer 51 which is a dTEOS layer or the like. As a result, a columnar portion LHRg, which becomes a lower structure of the columnar portion HRf, is formed.

Further, the insulating layer 57 is also formed on the exposed surface of the stacked body ULMs and the upper surface of the insulating layer 51. In this case, the insulating layer 57 formed on the upper surface of the insulating layer 51 in the stepped portion LSPs is arranged at a height position corresponding to the bottom surface of the stacked body ULMs, as illustrated in FIGS. 8A and 8B.

Note that the processing steps illustrated in FIGS. 5A to 5D described above may not be performed on the stepped portion LSPs; instead, the processing steps illustrated in FIGS. 7B and 8B may allow the lower structure of the columnar portion HRs to be formed all at once together with the plurality of columnar portions LHRg which becomes the lower structure of the columnar portion HRf.

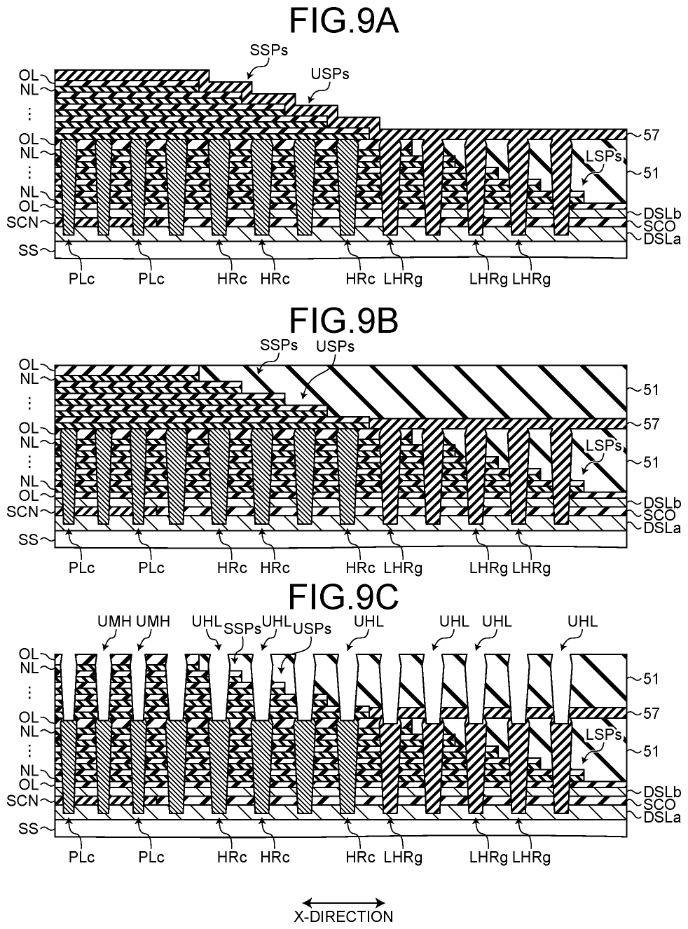

FIGS. 9A to 9C are cross-sectional views along the X-direction of regions that will later become the memory region MR and the step region SR, which is similar to FIGS. 4A to 4E and FIGS. 6A to 6C described above.

FIG. 9A illustrates how the columnar portion LHRg is formed in the stepped portion LSPs. As illustrated in FIG. 9A, the insulating layer 57 is also formed on the upper surface of the insulating layer 51 in the stepped portion LSPs, on the upper surface of each step of the stepped portions USPs and SSPs, and on the upper surface of the stacked body ULMs in a region that will later become the memory region MR.

In this way, when filling the hole LHL that forms the lower structure of the columnar portion HRf, the insulating layer 57 formed on the upper surface of the insulating layer 51 or the like may be left without being removed using CMP or the like. Note that in the subsequent drawings, illustrations of the top surface of each step of the stepped portions USPs and SSPs and illustrations of the insulating layer 57 on the top surface of the stacked body ULMs are omitted, except for the insulating layer 57 on the top surface of the insulating layer 51 of the stepped portion LSPs.

As illustrated in FIG. 9B, the insulating layer 51 is formed that covers the stepped portions USPs and SSPs and reaches the height of the upper surface of the stacked body ULMs. The insulating layer 51 is also formed in the outer regions of the stepped portions USPs and SSPs. The insulating layer 51 is obtained by forming a dTEOS layer using plasma CVD or the like, similar to the processing illustrated in FIG. 4C described above.

As a result, the insulating layer 51 is formed that covers the stepped portions LSPs, USPs, and SSPs and reaches the height of the upper surface of the stacked body ULMs. Further, the insulating layer 57 is interposed at a height position of the insulating layer 51 between the stacked body LLMs and the stacked body ULMs.

As illustrated in FIG. 9C, the plurality of memory holes UMH and the plurality of holes UHL extending in the stacking direction at the height position of the stacked body ULMs are formed, for example, at once. The memory hole UMH is a portion that will later become the upper structure of the pillar PL. The hole UHL is a portion that will later become the upper structure of any of the columnar portions HRm, HRs, and HRf.

The plurality of memory holes UMH is arranged in a region that will later become the memory region MR, and penetrates through the stacked body ULMs to reach the upper ends of the pillars PLC formed in the stacked body LLMs.

Some of the plurality of holes UHL are arranged at positions overlapping with the stepped portions USPs and SSPs in the stacking direction and penetrate the insulating layer 51 and the stacked body ULMs to reach the upper end of the columnar portion HRc formed in the stacked body LLMS.

Some others of the plurality of holes UHL are arranged at positions overlapping with the stepped portion LSPs in the stacking direction, penetrating the insulating layer 51 to reach the upper ends of the columnar portions LHRg formed in the stacked body LLMs.

In this regard, the columnar portion LHRg is, for example, a single-substance or the like of the insulating layer 57. For this reason, upon forming the hole UHL by penetrating the insulating layer 51, which is made of the same material, it is difficult to ensure a selectivity with the insulating layer 57. The amount of recess at the upper end of the columnar portion LHRg may be larger than that at the upper ends of the pillar PLC and the columnar portion HRc. In this case, the recess at the upper end of the columnar portion LHRg may be formed near the center of the columnar portion LHRg when viewed from the stacking direction.

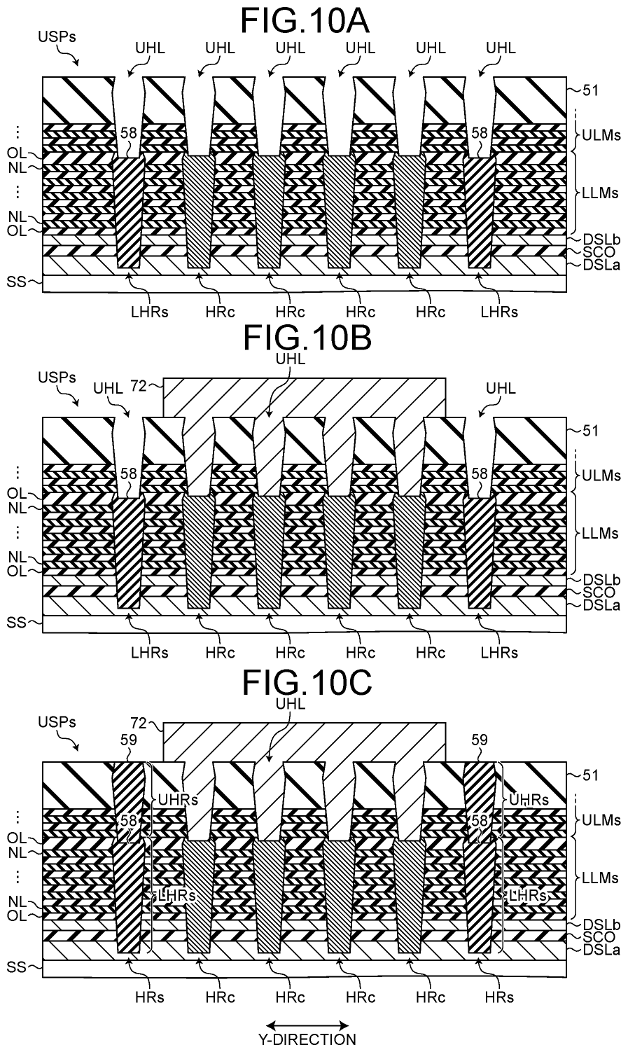

FIGS. 10A to 10C are cross-sectional views of the stepped portion USPs along the Y-direction, similar to FIGS. 5A to 5D, FIG. 7A, and FIG. 8A described above.

FIG. 10A illustrates how the plurality of holes UHL is formed in the stepped portion USPs. As illustrated in FIG. 10A, the lower ends of the plurality of holes UHL reach the columnar portions HRc of the stacked body LLMs. However, as described above, the columnar portions LHRS, which will later become the lower structure of the columnar portion HRs, are formed at both ends in the left-right direction of the drawing, and at the positions corresponding to these, the lower end of the hole UHL reaches the columnar portion LHRs.

As illustrated in FIG. 10B, the holes UHR reaching the plurality of columnar portions HRc are covered with a mask layer 72 such as a resist layer, excluding both ends in the left-right direction of the drawing. Similarly, the mask layer 72 also covers the portion of the stepped portion LSPs except for the hole UHL that will be adjacent to the plate-like contact LI later. In addition, the mask layer 72 covers the entire regions of both the stepped portion SSPs and the region that will later become the memory region MR.

As illustrated in FIG. 10C, in the stepped portions LSPs and USPs, the holes UHL at both left and right ends exposed from the mask layer 72 are filled with an insulating layer 59 such as a silicon oxide layer, similar to the processing in FIG. 5B described above, to form the columnar portions UHRs. The insulating layer 59 is also a silicon oxide layer or the like having a lower density than the insulating layer 51 which is a dTEOS layer or the like.

As a result, the columnar portions HRs that will later be adjacent to the plate-like contacts LI are formed. In this case, the insulating layer 59 is also formed on the upper surface of the stacked body ULMs. The insulating layer 59 on the upper surface may be removed using CMP or the like or may be left without being removed.

Note that the processing steps illustrated in FIGS. 5A to 5D described above may not be performed in the stepped portion USPs, and the hole LHL that will later be adjacent to the plate-like contact LI may be filled with the sacrificial layer 26. Then, following the processing illustrated in FIG. 10A, the sacrificial layer 26 at the bottom of the hole UHL may be removed through the plurality of holes UHL to open the hole LHL. Subsequently, the single-substance of the insulating layer 59 may be formed at once in the holes LHL and UHL at both left and right ends after covering the portions except for the hole UHL that will be adjacent to the plate-like contact LI later with the mask layer 72.

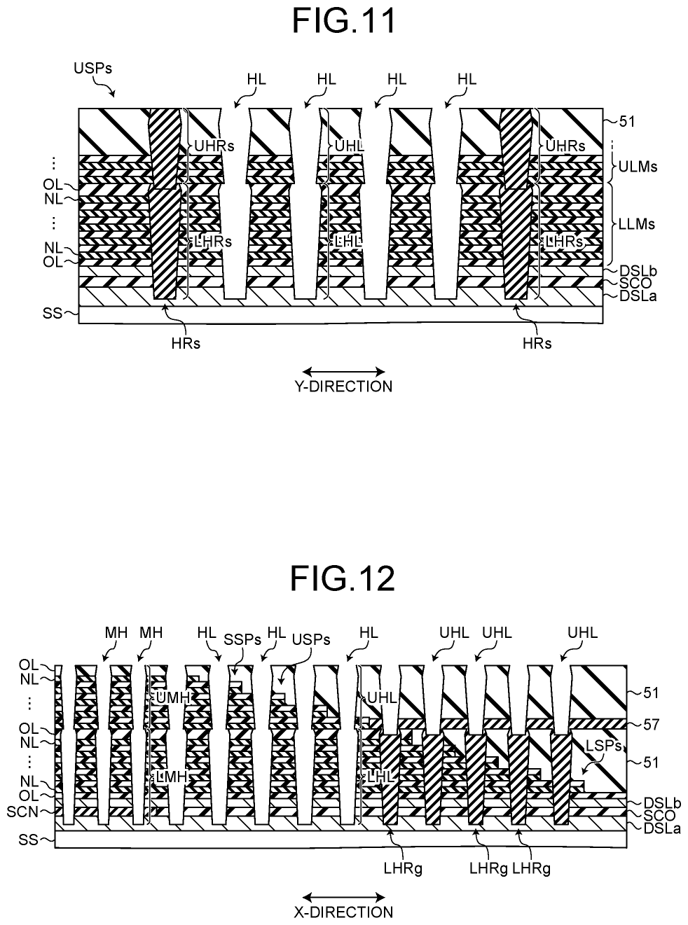

Then, states in which a multilayer structure is formed in each hole are illustrated with reference to FIGS. 11 to 18B.

FIG. 11 is a cross-sectional view of the stepped portion USPs along the Y-direction, similar to FIGS. 10A to 10C described above. More specifically, FIG. 11 illustrates processing subsequent to the processing of FIGS. 10A to 10C.

As illustrated in FIG. 11, after the columnar portion HRs is formed, the mask layer 72 is removed by ashing using oxygen plasma or the like, and the sacrificial layer 26 is further removed from the columnar portion HRC at the bottom of the hole UHL. As a result, the plurality of holes LHL is opened at the bottoms of the plurality of holes UHL and penetrates through the insulating layer 51, the stacked bodies ULMs and LLMs, the upper source line DSLb, and the intermediate insulating layer SCO to form a plurality of holes HL reaching the lower source line DSLa.

In this case, also in the stepped portion SSPs, the sacrificial layer 26 is removed from the columnar portion HRc, and the hole LHL is opened. Furthermore, in the region that will later become the memory region MR, the sacrificial layer 26 is removed from the pillar PLC formed in the stacked body LLMs, and the plurality of memory holes LMH is opened again.

FIG. 12 is a cross-sectional view along the X-direction of a region that will later become the memory region MR and the step region SR, which is similar to FIGS. 4A to 4E, 6A to 6C, and 9A to 9C described above.

As illustrated in FIG. 12, in the region that will later become the memory region MR, the holes LMH are opened at the bottoms of the plurality of memory holes UMH, and penetrate through the stacked bodies ULMs, LLMs, the upper source line DSLb, and the intermediate sacrificial layer SCN to form a plurality of memory holes MH that reaches the lower source line DSLa. In addition, as described above, a plurality of holes HL is formed in the stepped portions SSPs and USPs.

On the other hand, in the stepped portion LSPS, the columnar portion UHRs is formed in the hole UHL connected to the columnar portion LHRs among the plurality of holes UHL, as in the case of the stepped portion USPs illustrated in FIGS. 10A to 10C and 11. The other holes UHL do not change from that state having the columnar portion LHRg as the lower structure.

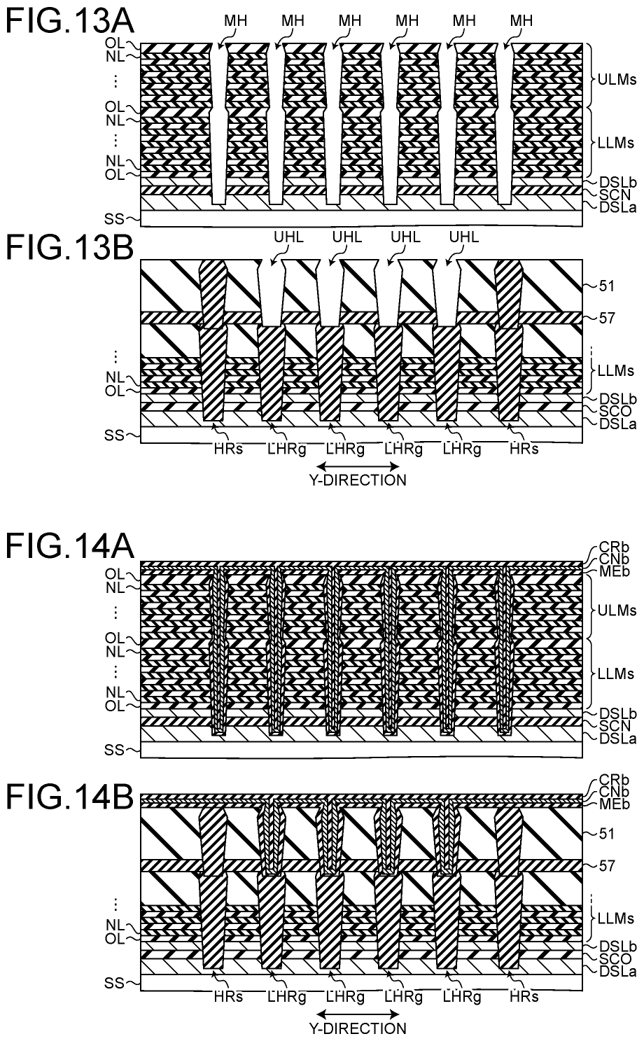

FIGS. 13A to 18B are cross-sectional views along the Y-direction of a region that will later become the memory region MR or the step region SR. More specifically, “A” of FIGS. 13A to 18B are cross-sectional views of a region that will later become the memory region MR, and “B” of FIGS. 13A to 18B are cross-sectional views of the stepped portion LSPs, similar to FIGS. 7B and 8B described above.

As illustrated in FIGS. 13A and 14A, in the region that will later become the memory region MR, a multilayer insulating layer MEb, a semiconductor layer CNb, and an insulating layer CRb are formed in this order in the memory hole MH. As a result, the multilayer insulating layer MEb and the semiconductor layer CNb are arranged on the side surface of the memory hole MH and the bottom surface where the lower source line DSLa is exposed, and the center of the memory hole MH is filled with the insulating layer CRb.

The multilayer insulating layer MEb is an insulating layer with a multilayer structure that will later become the memory layer ME. The semiconductor layer CNb is a layer that will later become the channel layer CN. The insulating layer CRb is a silicon oxide layer or the like that will later become the core layer CR.

The multilayer insulating layer MEb, the semiconductor layer CNb, and the insulating layer CRb are also formed in this order on the upper surface of the stacked body ULMs.

Further, although not illustrated, in the stepped portions SSPs and USPs, the multilayer insulating layer MEb and the semiconductor layer CNb are also formed on the side surfaces of the holes HL and the bottom surfaces where the lower source line DSLa is exposed, and the center of the hole HL is filled with the insulating layer CRb by the processing illustrated in FIGS. 13A and 14A.

As illustrated in FIGS. 13B and 14B, in the stepped portion LSPs, the multilayer insulating layer MEb, the semiconductor layer CNb, and the insulating layer CRb are formed in this order in the hole UHL by the processing illustrated in FIGS. 13A and 14A. As a result, the multilayer insulating layer MEb and the semiconductor layer CNb are arranged on the side surface of the hole UHL and the bottom surface where the upper end of the columnar portion LHRg is exposed, and the center of the hole UHL is filled with the insulating layer CRb.

In the step region SR including the stepped portion LSPs or the like, the multilayer insulating layer MEb, the semiconductor layer CNb, and the insulating layer CRb are also formed on the upper surface of the insulating layer 51 in this order.

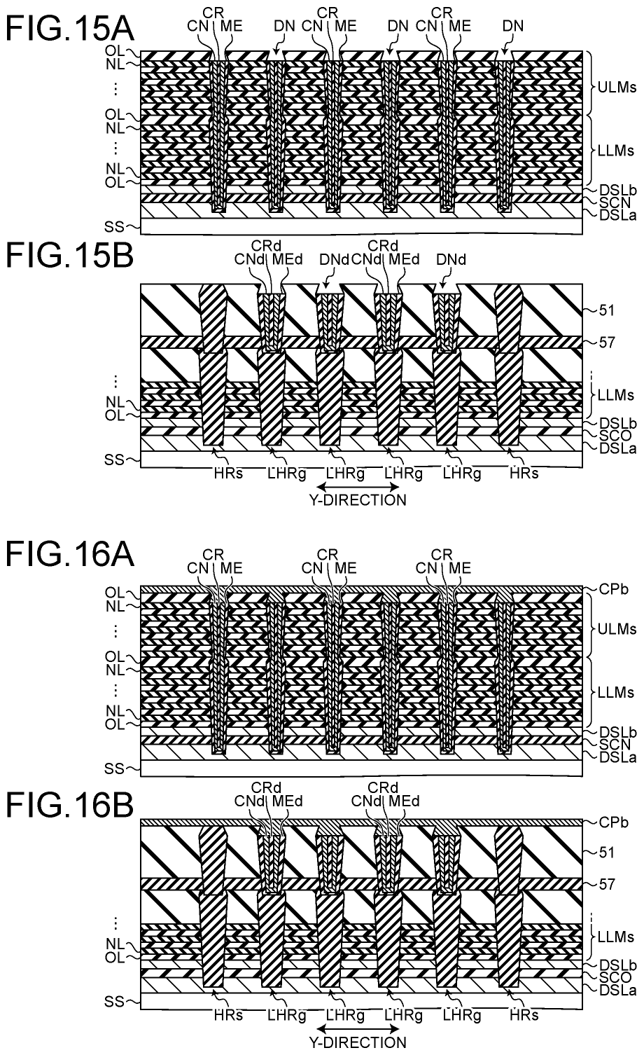

As illustrated in FIG. 15A, in the region that will later become the memory region MR, the insulating layer CRb, the semiconductor layer CNb, and the multilayer insulating layer MEb are sequentially etched back to remove them from the upper surface of the stacked body ULMs, and a depression DN is formed in the upper end of the memory hole MH.

As a result, the memory layer ME, the channel layer CN, and the core layer CR are formed in the memory hole MH in this order from the outer circumferential side.

As illustrated in FIG. 15B, also in the stepped portion LSPs, the insulating layer CRb, the semiconductor layer CNb, and the multilayer insulating layer MEb are sequentially removed from the upper surface of the insulating layer 51 by the processing of FIG. 15A, and a depression DNd is formed in the upper end of the hole UHL. In addition, although not illustrated, in the stepped portions SSPs and USPs, the depression DNd is similarly formed at the upper end of the hole HL.

As a result, the dummy layers MEd, CNd, and CRd are formed in order from the outer circumferential side within the hole UHL or throughout the hole HL.

Note that when etching back the insulating layer CRb, the semiconductor layer CNb, and the multilayer insulating layer MEb, the upper surface of the columnar portion HRs filled with an identical type of the insulating layer 59 partially to the multilayer insulating layer MEb and to the insulating layer CRb may be protected by a mask layer or the like, which is not illustrated.

As illustrated in FIG. 16A, in a region that will later become the memory region MR, a semiconductor layer CPb is formed in the depression DN at the upper end of the memory hole MH. The semiconductor layer CPb is a layer that will later become the cap layer CP. The semiconductor layer CPb is also formed on the upper surface of the stacked body ULMs.

As illustrated in FIG. 16B, also in the stepped portion LSPs, the depression DNd at the upper end of the hole UHL is filled with the semiconductor layer CPb, and the upper surface of the insulating layer 51 is covered with the semiconductor layer CPb by the processing illustrated in FIG. 16A. In addition, although not illustrated, in the stepped portions SSPs and USPs, the depression DNd at the upper end of the hole HL is similarly filled with the semiconductor layer CPb.

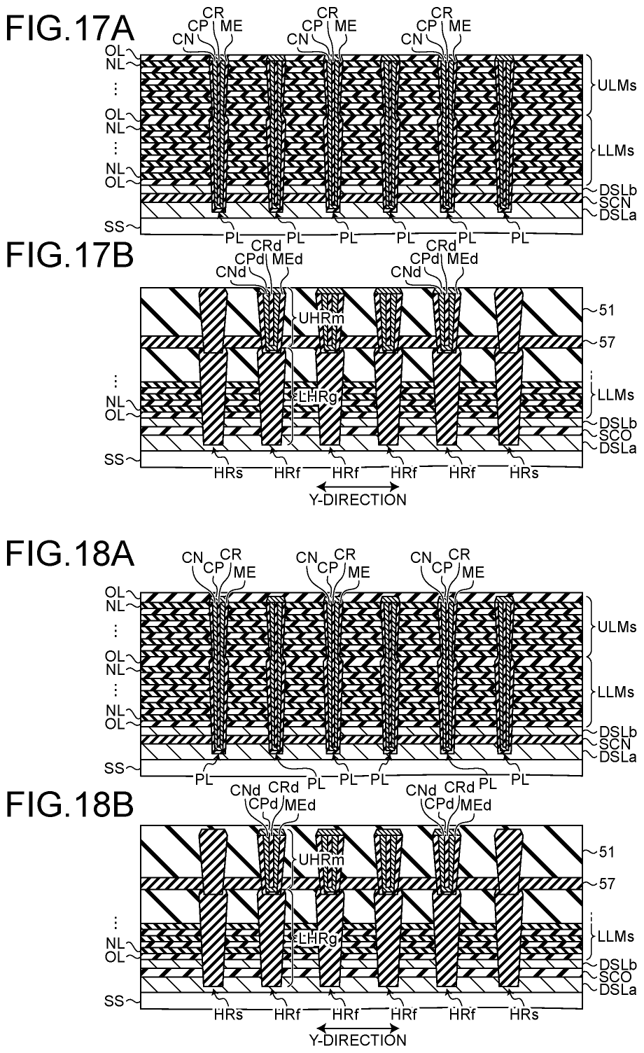

As illustrated in FIGS. 17A and 18A, in a region that will later become the memory region MR, the semiconductor layer CPb on the upper surface of the stacked body ULMs is removed using CMP or the like to form the cap layer CP at the upper end of the memory hole MH. Further, the uppermost insulating layer OL of the stacked body ULMs, which has been thinned using CMP or the like, is re-stacked.

As a result, the pillar PL in which the cap layer CP is buried in the uppermost insulating layer OL is formed. However, at this point, the memory layer ME covers the entire sidewall of the pillar PL, and a part of the sidewall of the channel layer CN is not exposed from the memory layer ME.

As illustrated in FIGS. 17B and 18B, also in the stepped portion LSPs, the dummy layer CPd is formed at the upper end part and the columnar portion UHRm with lower end connected to the columnar portion LHRg is formed by the processing of FIGS. 17A and 18A. As a result, the columnar portion HRf including the columnar portions LHRg and UHRm is formed. In addition, although not illustrated, in the stepped portions SSPs and USPs, the columnar portion HRm having the dummy layer CPd formed at the upper end portion is formed.

Note that the columnar portions HRm and HRf are formed as dummy pillars that will serve as a support structure during a replacement processing to be described later, and do not contribute to the function of the semiconductor storage device 1. Thus, the columnar portions HRm and HRf do not need to have the dummy layer CPd, and the processing of FIG. 16B does not need to be performed on the columnar portions HRm and HRf. In this case, the depressions DNd at the upper ends of the holes HL and UHL can be backfilled with, for example, an insulating layer.

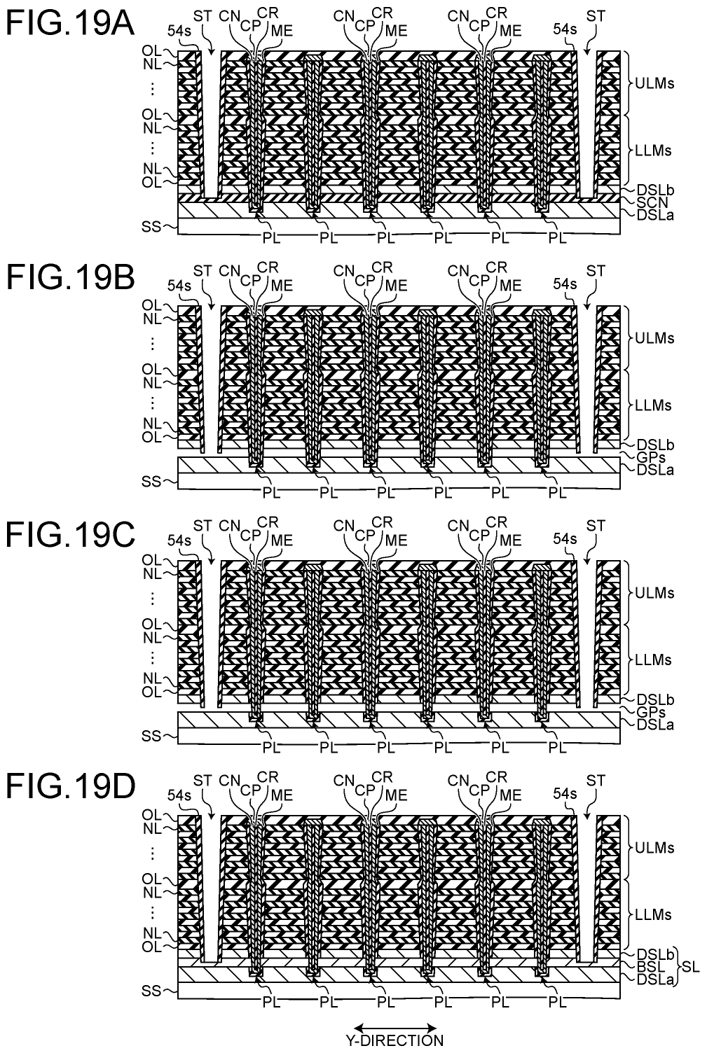

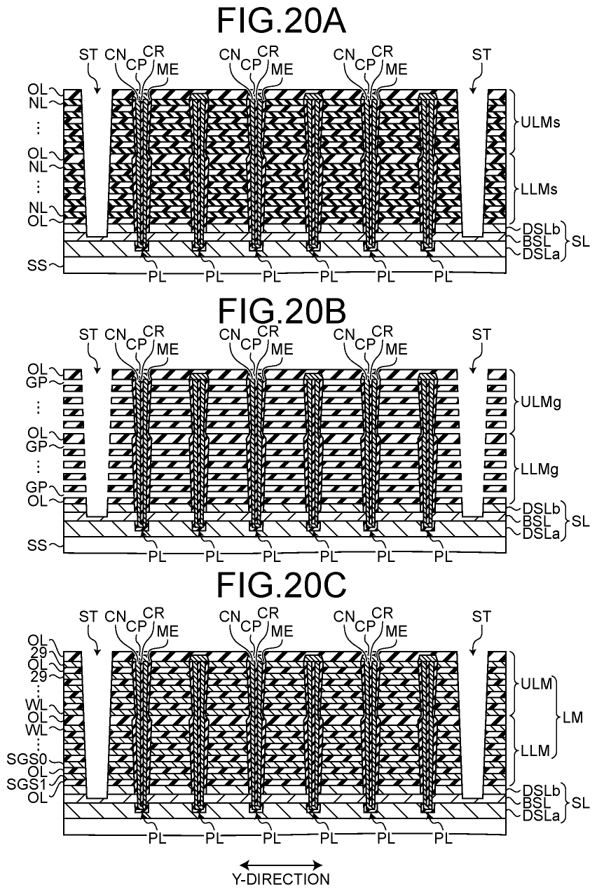

Then, how to form the source line SL and word line WL will be illustrated with reference to FIGS. 19A to 20C.

FIGS. 19A to 20C are cross-sectional views along the Y-direction of a region that will later become the memory region MR, similar to “A” of FIGS. 13A to 18B described above.

As illustrated in FIG. 19A, a slit ST is formed that penetrates the stacked bodies ULMs and LLMs and the upper source line DSLb and reaches the intermediate sacrificial layer SCN. Furthermore, an insulating layer 54s is formed on the sidewalls of the slit ST facing each other in the Y-direction.

The slit ST has a tapered or bowing vertical cross section in the Y-direction and also extends in the direction along the X-direction inside the stacked bodies LLMs and ULMs. Thus, in the not-illustrated step region SR, the lower end portion of the slit ST reaches the intermediate insulating layer SCO.

In this case, due to the difference in hardness between the stacked bodies LLMs and ULMs in which the multiple insulating layers NL and OL are alternately stacked and the insulating layer 51 which is a single-substance such as a silicon oxide layer, the degree of the tapered or bowing shape of the slit ST becomes more noticeable in the step region SR covered with the insulating layer 51.

Further, the distance that the slit ST extends in the insulating layer 51 in the stacking direction of the stacked bodies LLMs and ULMs increases as one goes from the stepped portion SSPs of the step region SR to the stepped portion USPs and further to the stepped portion LSPs. Thus, the degree of the tapered or bowing shape of the slit ST increases from the stepped portion SSPs to the stepped portion LSPs.

As illustrated in FIG. 19B, a removal solution for the intermediate sacrificial layer SCN, such as hot phosphoric acid, is caused to flow in to remove the intermediate sacrificial layer SCN sandwiched between the lower source line DSLa and the upper source line DSLb through the slit ST whose sidewall is protected by the insulating layer 54s.

As a result, a gap layer GPs is formed between the lower source line DSLa and the upper source line DSLb. In addition, a part of the memory layer ME at the outer periphery of the pillar PL is exposed in the gap layer GPs.

At this point, the sidewall of the slit ST is protected by the insulating layer 54s, it is suppressed that even the insulating layer NL in the stacked bodies LLMs and ULMs is removed. Furthermore, in the not-illustrated step region SR, there is no intermediate sacrificial layer SCN between the lower source line DSLa and the upper source line DSLb, and no gap layer GPs is formed.

As illustrated in FIG. 19C, chemical solutions are appropriately flowed into the gap layer GPs through the slit ST to remove sequentially the block insulating layer BK, the charge storage layer CT, and the tunnel insulating layer TN (see FIGS. 2C and 2D) of the memory layer ME exposed in the gap layer GPs. As a result, the memory layer ME is removed from a portion of the sidewall of the pillar PL, and a portion of the inner channel layer CN is exposed within the gap layer GPS.

As illustrated in FIG. 19D, a raw material gas such as amorphous silicon is injected through the slit ST whose sidewall is protected by an insulating layer 54s, and the gap layer GPs is filled with amorphous silicon or the like. In addition, the support substrate SS is heat-treated to poly-crystallize the amorphous silicon filled in the gap layer GPs to form an intermediate source line BSL containing polysilicon or the like.

As a result, the portion of the channel layer CN of the pillar PL is connected to the source line SL on the side surface via the intermediate source line BSL.

In this case, in the not-illustrated step region SR, no gap layer GPs is formed between the lower source line DSLa and the upper source line DSLb. Thus, for example, the dummy layer MEd of the columnar portion HRm is not removed, and the intermediate source line BSL is not formed.

It is preferable that the columnar portion HRm, which is a dummy pillar, has no electrical continuity with the source line SL. As described above, in the step region SR excluding the memory region MR, by arranging the intermediate insulating layer SCO instead of the intermediate sacrificial layer SCN between the lower source line DSLa and the upper source line DSLb, the columnar portion HRm is suppressed from being electrically connected to the source line SL.

As illustrated in FIG. 20A, the insulating layer 54s on the sidewall of the slit ST is once removed.

As illustrated in FIG. 20B, a removal liquid for the insulating layer NL, such as hot phosphoric acid, is allowed to flow into the stacked bodies LLMs and ULMs from the slit ST to remove the insulating layer NL of the stacked bodies LLMs and ULMs. As a result, stacked bodies LLMg and ULMg having the plurality of gap layers GP from which the insulating layers NL between the insulating layers OL has been removed are formed.

Note that the stacked bodies LLMg and ULMg that include the plurality of gap layers GP have a fragile structure. In the region that will later become the memory region MR, the plurality of pillars PL supports such fragile stacked bodies LLMg and ULMg. On the other hand, in the region that will later become the stepped portion SSP, the plurality of columnar portions HRm supports these stacked bodies LLMg and ULMg. In the region that will later become the stepped portion USP, two types of columnar portions HRm and HRs support the stacked bodies LLMg and ULMg. In the region that will later become the stepped portion LSP, the other two types of columnar portions HRf and HRs support the stacked body LLMg.

Such a support structure of the pillar PL and the columnar portions HRm, HRs, and HRf suppresses the remaining insulating layer OL from being bent and the stacked bodies LLMg and ULMg from being distorted or collapsed.

As illustrated in FIG. 20C, a raw material gas of a conductive material such as tungsten or molybdenum is injected into the stacked bodies LLMg and ULMg from the slit ST, and the gap layer GP of the stacked bodies LLMg and ULMg is filled with the conductive material to form the plurality of word lines WL or the like. As a result, the stacked body LM including the stacked bodies LLM and ULM in which the plurality of word lines WL or the like and the plurality of insulating layers OL are alternately stacked one layer at a time is formed.

Note that the uppermost layer 29 and the second conductive layer 29 from the uppermost layer 29 of the stacked body ULM are partitioned into patterns of the plurality of selection gate lines SGD by forming a separation layer SHE penetrating them later.

As described above, the processing of forming the intermediate source line BSL from the intermediate sacrificial layer SCN and the processing of forming the word line WL or the like from the insulating layer NL are also called replacement processing.

Then, the insulating layer 54 is formed on the sidewall of the slit ST, and the conductive layer 24 is filled in the insulating layer 54 to form the plate-like contact LI that will become a source line contact. However, the slit ST may be filled with the insulating layer 54 or the like without forming the conductive layer 24, thereby forming a plate-like member that does not function as a source line contact.

Further, by forming a groove penetrating one or more conductive layers 29 including the uppermost conductive layer 29 of the stacked body ULM and filling the groove with the insulating layer 56, the separation layer SHE is formed to partition these conductive layers 29 into a pattern of selection gate lines SGD.

In addition, a plurality of contact holes is formed all at once to penetrate the insulating layer 51 and reach the word lines WL and the selection gate lines SGD and SGS constituting each step of the stepped portions SSP, USP, and LSP and the insulating layer 55 and the conductive layer 25 are formed within the contact hole. As a result, the contacts CC are formed which are respectively connected to the plurality of word lines WL and the selection gate lines SGD and SGS.

Subsequently, the insulating layer 52 is formed on the upper surface of the stacked body LM and the upper surface of the insulating layer 51 covering the step region SR, and the plug V0 is formed to penetrate the insulating layer 52 and to be connected to the contact CC. In addition, the plug CH is formed to penetrate through the insulating layer 52 and to be connected to the plate-like contact LI and the pillar PL. Furthermore, the insulating layer 53 is formed on the insulating layer 52, and the upper layer wiring MX, the bit line BL, or the like connected to the plugs V0 and CH are formed in the insulating layer 53. In addition, on the upper surface of the insulating layer 53, electrode pads and the like are formed to establish electrical continuity with the peripheral circuit CBA.

Note that the plugs V0 and CH, the upper layer wiring MX, the bit line BL, or the like may be formed all at once by using, for example, a dual damascene method or the like.

Additionally, the peripheral circuit CBA is formed on the semiconductor substrate SB that is separate from the support substrate SS on which the stacked body LM is formed, and covered with an insulating layer 40. In the insulating layer 40, contacts, vias, wiring, or the like are formed to draw the peripheral circuit CBA to the surface of the insulating layer 40 and are connected to electrode pads or the like formed on the upper surface of the insulating layer 40.

Subsequently, the support substrate SS and the semiconductor substrate SB are bonded together at their respective insulating layers 50 and 40, and the electrode pads in the insulating layers 50 and 40 are connected. Then, the support substrate SS is polished away to expose the source line SL, and the electrode film EL is connected through the insulating layer 150 in which the plug PG is formed.

The description above allows the semiconductor storage device 1 according to the embodiment to be manufactured.

In the manufacturing process of a semiconductor storage device such as a three-dimensional nonvolatile memory, a sacrificial layer in a stacked body may be replaced with a conductive layer to form a stacked body in which a conductive layer and an insulating layer are stacked. In this case, the columnar portions may be arranged, for example in the step region, to support a fragile stacked body including a plurality of gap layers during the replacement processing. The columnar portion has a structure in which, for example, a hole penetrating the stacked body is filled with an insulating layer such as a silicon oxide layer.

However, upon filling holes penetrating the stacked body with an insulating layer, incomplete filling of the insulating layer may cause voids within the columnar portions. In addition, upon forming slits for replacing the stacked body, forming contact holes in the step region, or similar manufacturing processes, these slits or contact holes may come into contact with the columnar portions. In this case, if the void in the columnar portion communicates with the slit or contact hole, the conductive layer will enter the void in the columnar portion while performing the subsequent replacement processing or filling the contact hole with a conductive layer, resulting in a risk that the withstand voltage will be insufficient between multiple word lines.

Further, in the case where the columnar portion is made of an insulating layer or the like, the insulating layer that makes up the columnar portion may shrink due to thermal treatment in the subsequent manufacturing process. In this case, due to contraction of the plurality of columnar portions, the entire area where these columnar portions are arranged may sink in the stacking direction of the stacked body compared to other areas such as the memory area supported by the pillars. In other words, this results in irregularities on the upper surface of the semiconductor storage device being manufactured.

As a result, in processing or the like using lithography technology, for example, the aim may be misaligned in the area where the subsidence has occurred, failing to normal exposure. In addition, for example, in the processing or the like of polishing away a conductive material embedded in a hole or groove from the upper surface of a stacked body, the residual conductive material may be left in the area where the subsidence has occurred.

Thus, it is conceivable that the columnar portions be made of a material that has a higher Young's modulus and is harder than, for example, a silicon oxide layer. In this case, for example, if the layer structure of the columnar portion is unified with the layer structure of the pillar including a channel layer having a high Young's modulus, the columnar portion and the pillar can be easily formed at once.

However, even if the columnar portion has an identical layer structure to the pillar, there remains the issue of a drop in withstand voltage between the word lines due to contact between the slit or contact hole and the columnar portion.

In other words, the identical type of material to the sacrificial layer to be replaced upon forming a stacked body including a plurality of conductive layers may be used for the charge storage layer of the pillar. If the columnar portion contains a nitride layer or the like that corresponds to the charge storage layer, upon forming a slit for replacing the stacked body, there is a concern that the slit and the columnar portion will come into contact and the nitride layer of the columnar portion will be exposed inside the slit. In this case, if the replacement processing is performed through the slit, even the nitride layer of the columnar portion will be replaced with the conductive layer through the exposed part, resulting in a risk of insufficient withstand voltage between multiple word lines as described above.

Further, the conditions for forming the contact hole have a low selectivity with respect to the nitride layer, and there is a concern that the nitride layer in the columnar portion may be removed due to contact with the contact hole. Then, if the contact hole is filled with a conductive layer, the void in the columnar portion created upon removing the nitride layer is also filled with the conductive layer, resulting in sometimes insufficient withstand voltage between multiple word lines.

According to the semiconductor storage device 1 of the embodiment, the plurality of columnar portions HRf individually includes the columnar portion LHRg that is a single-substance of the insulating layer 57 extending in the stacking direction on the lower side of the stacked body LM and the columnar portion UHRm arranged at a height position on the upper layer side of the stacked body LM in correspondence with the columnar portion LHRg.

As described above, in the stepped portion LSP where the contact CC extends over a long distance in the stacking direction, the risk of contact between the columnar portion HRf and the contact CC increases, for example, in the lower structure side.

According to the above configuration, the lower structure of the columnar portion HRf is made of a single-substance of the insulating layer 57, so even if the columnar portion HRf and the contact hole come into contact with each other on the lower structure side, it is possible to suppress the intrusion of the conductive layer 25 of the contact CC into the columnar portion HRf.

In this regard, as mentioned above, upon forming the hole UHL, there is a concern that the dummy layer CTd will be formed in the recess generating in the columnar portion LHRg and that the above-mentioned void will also be formed in the insulating layer 57 of the columnar portion LHRg constituting the lower structure.

However, in the case where a recess occurs in the columnar portion LHRg, it is considered that the vicinity of the center of the columnar portion LHRg as viewed from the stacking direction becomes depressed. Thus, there is almost no possibility that the contact hole in contact with the columnar portion LHRg will reach the deep part of the columnar portion LHRg and communicate with the dummy layer CTd formed in the recess of the columnar portion LHRg.

Further, in the case of filling the hole LHL that penetrates only the stacked body LLM, which is the lower layer portion of the stacked body LM, it is conceivable that the void is less likely to occur compared to filling an insulating layer in a hole extending from the upper layer to the lower layer of the stacked body LM. If the void occurs, it is expected to be relatively small in volume and remain near the center of the columnar portion LHRg.

Thus, even if contact with the columnar portion LHRg occurs, the contact hole is suppressed from reaching the deep part of the columnar portion LHRg and communicating with the void. Thus, it is possible to suppress the conductive layer 25 of the contact CC from entering the columnar portion LHRg.

As described above, it is possible to suppress the influence on electrical characteristics due to interference between the dummy pillar and other components.

According to the semiconductor storage device 1 of the embodiment, the stepped portions USP and SSP are provided with the plurality of columnar portions HRm extending in the stacking direction. The plurality of columnar portions HRm individually includes the dummy layer CNd extending in the stacking direction from the upper layer side to the lower layer side of the stacked body LM, the dummy layer TNd covering the sidewall of the dummy layer CNd, the dummy layer BKd covering the sidewall of the dummy layer TNd, and the dummy layer CTd including different materials from the dummy layers TNd and BKd and interposed between the dummy layers TNd and BKd.

The subsidence of the stacked body described above becomes more pronounced as the number of layers in the stacked body increases. According to the above configuration, among the stepped portions LSP, USP, and SSP, in the stepped portions USP and SSP, in which the number of stacked layers of the stacked body LM increases, the columnar portions HRm including the dummy layer CNd penetrating the entire stacked body LM in the stacking direction are arranged. The dummy layer CNd is, as mentioned above, a semiconductor layer with a higher Young's modulus than, for example, an oxide silicon layer.

This makes it possible to suppress the subsidence of the stacked body LM in the stepped portions USP and SSP where subsidence is more likely to occur. In addition, for example, the columnar portion HRm, which has higher strength than a columnar portion whose entire structure is constituted by a single insulating layer, enables further suppression of deflection in the stacked bodies LLMg and ULMg during the replacement processing.

On the other hand, in the stepped portions USP and SSP, the word line WL or the like to be connected is located at a relatively shallow position, so the distance that the contact CC extends in the stacking direction is short. Thus, even if the columnar portion HRm or the contact CC is misaligned or the columnar portion HRm is tilted, the risk of contact between the columnar portion HRm and the contact CC is low, so it is possible to place the columnar portion HRm including the dummy layer CTd such as a silicon nitride layer.

According to the semiconductor storage device 1 of the embodiment, the plurality of columnar portions HRs arrayed in the direction along the X-direction adjacent to the plurality of plate-like contacts LI extending in the X-direction on both sides of the plurality of plate-like contacts LI in the stepped portions LSP and USP in the Y-direction. Each of the plurality of columnar portions HRs includes the insulating layers 59 and 58 respectively extending in the stacking direction at a height position on the upper layer side and on the lower layer side of the stacked body LM.

According to the above configuration, in the stepped portions LSP and USP where the thickness of the insulating layer 51 gradually increases and the width of the plate-like contact LI increases, the columnar portion HRs constituted by the insulating layers 59 and 58 is arranged at a position where there is a high risk of contact with the plate-like contact LI over the height positions from the upper layer side to the lower layer side of the stacked body LM. This makes it possible to suppress a portion of the columnar portion HRs from being replaced with a conductive layer by the replacement processing even if the columnar portion HRs and the slit ST come into contact with each other.

According to the semiconductor storage device 1 of the embodiment, in the stepped portion SSP where the selection gate line SGD is processed into a step shape, the plurality of columnar portions HRm is arranged including the positions adjacent to the plurality of plate-like contacts LI.

As described above, in the stepped portion SSP where the number of layers in the stacked bodies LM is large and the thickness of the insulating layer 51 is thin, the stacked body LM subsides significantly, while the widening of the slit ST having a tapered shape or a bowing shape in the Y-direction is suppressed. Thus, arranging the columnar portion HRm over the entire area of the stepped portion SSP makes it possible to further suppress the subsidence of the stacked body LM without fear of contact with the slit ST.

### FIRST MODIFICATION

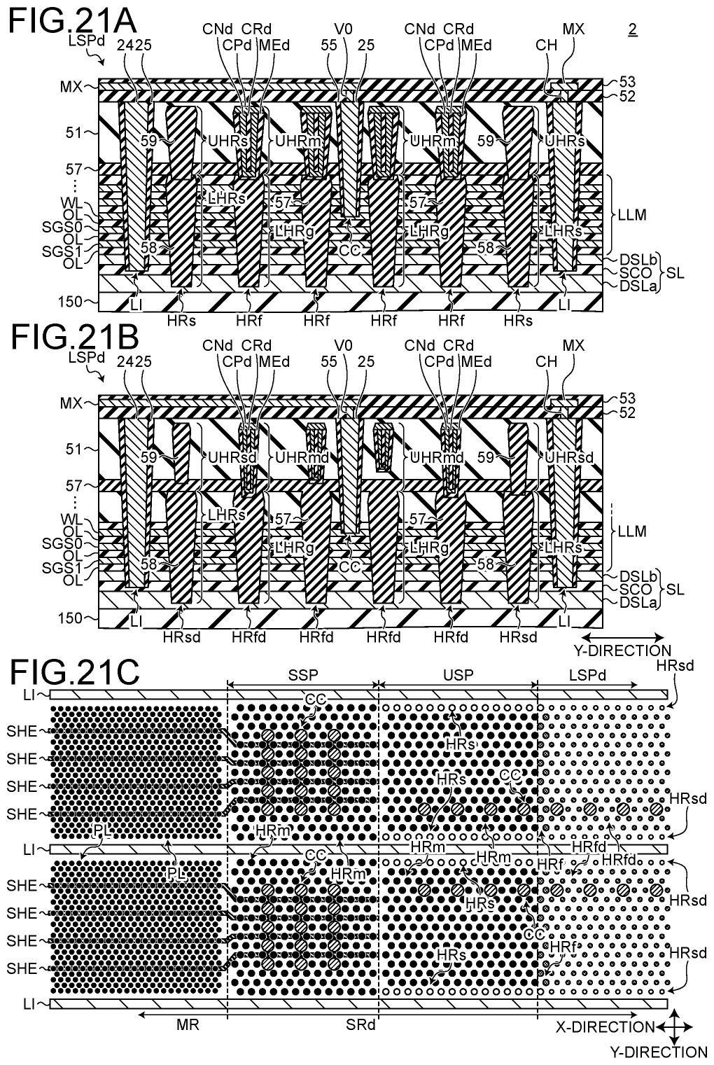

A semiconductor storage device 2 according to a first modification of the embodiment is now described with reference to FIGS. 21A to 21C. The semiconductor storage device 2 of the first modification differs from the above-described embodiment in that it includes a columnar portion HRfd whose upper and lower structures have different XY cross-sectional areas in place of the above-described columnar portion HRf.

Note that in the following drawings, components identical to those in the above-described embodiments are denoted by identical reference numerals, and their descriptions may be omitted.

FIGS. 21A to 21C are diagrams illustrating an exemplary configuration of the semiconductor storage device 2 according to the first modification of the embodiment.

More specifically, FIG. 21A is a cross-sectional view along the Y-direction illustrating an exemplary configuration of the uppermost layer side of a stepped portion LSPd, and FIG. 21B is a cross-sectional view along the Y-direction illustrating an exemplary configuration of the columnar portion HRfd. In FIGS. 21A and 21B, the structures below the insulating layer 150 and above the insulating layer 53 are omitted.

FIG. 21C is an XY cross-sectional view of a partial region of the stacked body LM at the height position of the selection gate line SGD.

The semiconductor storage device 2 according to the first modification has a schematic configuration similar to that of the semiconductor storage device 1 according to the embodiment illustrated in FIG. 1 described above. In addition, the semiconductor storage device 2 has a configuration similar to that of the semiconductor storage device 1 of the above-described embodiment in the memory region MR and the stepped portions SSP and USP.

As illustrated in FIGS. 21A to 21C, in a step region SRd of the semiconductor storage device 2, in addition to the above-mentioned stepped portions USP and SSP, the stepped portion LSPd in which the word lines WL and the selection gate lines SGS belonging to the stacked body LLM are processed into a step shape is included. In the stepped portion LSPd, columnar portions HRf, HRs, HRfd, and HRsd are arranged.

The plurality of columnar portions HRf is arranged in a partial region near the top layer of the stepped portion LSPd. The plurality of columnar portions HRs is arranged at a position adjacent to the plate-like contact LI to correspond to the region where the columnar portions HRf are arranged in the X-direction.

In the stepped portion LSPd, the multiple columnar portions HRfd and HRsd are arranged in a region lower than the region where the columnar portions HRf and HRs are arranged. The plurality of columnar portions HRfd is arranged in a distributed manner in the lower region of the stepped portion LSPd, and the plurality of columnar portions HRsd is arranged at a position adjacent to the plate-like contact LI in the same level lower region of the stepped portion LSPd.

The columnar portions HRfd each include the columnar portion LHRg as a lower structure and include a columnar portion UHRmd extending in the stacking direction at the height position of the stacked body ULM as an upper structure. The columnar portion UHRmd includes the dummy layers MEd, CNd, and CRd in order from the outer circumferential side, for example, similar to the columnar portion UHRm of the above-described embodiment. The columnar portion UHRmd may include the dummy layer CPd.

The columnar portions HRsd each include the columnar portion LHRs as a lower structure and include a columnar portion UHRsd extending in the stacking direction at the height position of the stacked body ULM as an upper structure. The columnar portion UHRsd has, for example, a single-substance structure of the insulating layer 59, similar to the columnar portion UHRs of the above-described embodiment.

Similar to the columnar portions LHRg and LHRS, for example, the columnar portions UHRmd and UHRsd have a circular, elliptical, or oval shape as a cross-sectional shape in the direction along the XY plane, and have a tapered shape in which the diameter and cross-sectional area decrease from the upper end toward the lower end, or alternatively have a bowing shape in which the diameter and cross-sectional area are maximum between the upper end and the lower end.

However, the average cross-sectional area or maximum cross-sectional area in the direction along the XY plane of the columnar portions UHRmd and UHRsd is smaller than the average cross-sectional area or maximum cross-sectional area in the direction along the XY plane of the columnar portions LHRg and LHRs in the columnar portions HRfd and HRsd, respectively. In other words, the average diameter or maximum diameter of each of the columnar portions UHRmd and UHRsd is smaller than the average diameter or maximum diameter of the columnar portions LHRg and LHRs.

The columnar portions UHRmd and UHRsd each have a smaller diameter than the columnar portions LHRg and LHRS, so the holes formed in the insulating layer 51 upon forming the columnar portions UHRmd and UHRsd can have a higher aspect ratio than that of the above-described hole LHL formed in the stacked body LLM upon forming the columnar portions LHRg and LHRs, for example.

Thus, the lower end portions of each of the columnar portions UHRmd and UHRsd do not necessarily reach the columnar portions LHRg and LHRs due to slowing or the like of the etching reaction at the bottom of the hole upon forming holes that will later become the columnar portions UHRmd and UHRsd.

As a result, the amount of recess at the upper end of the columnar portion LHRg upon forming a hole that will later become the columnar portion UHRmd is reduced, and the lower end of the columnar portion UHRmd having the dummy layer CTd or the like is suppressed from reaching the height position of the upper layer part of the stacked body LLM.

As described above, even in the case where the XY cross-sectional area of the upper and lower structures is different, when viewed from the stacking direction of the stacked body LM, the central axis of the columnar portion UHRmd and the columnar portion LHRg and the central axes of the columnar portion UHRsd and the columnar portion LHRs substantially coincide with each other.

Moreover, even if the columnar portion HRfd is arranged in the stepped portion LSPd, as described above, the columnar portion HRf is arranged on the uppermost layer side of the stepped portion LSPd, that is, near the boundary with the stepped portion USP so that the columnar portions HRm and HRf, whose XY cross-sectional area of the upper structure is approximately equal, are adjacent to each other. This arrangement makes it possible to improve the processing accuracy of the columnar portion HRm arranged in the stepped portion USP at the boundary portion with the stepped portion LSPd.

According to the semiconductor storage device 2 of the first modification, each of the plurality of columnar portions HRfd includes the columnar portions LHRg and UHRmd. The columnar portion LHRg is a single-substance of the insulating layer 57 extending in the stacking direction on the lower side of the stacked body LM, and the columnar portion UHRmd is arranged at a height position on the upper layer side of the stacked body LM corresponding to the columnar portion LHRg. In addition, the maximum value of the cross-sectional area of the columnar portion LHRg as viewed from the stacking direction of the stacked body LM is larger than the maximum value of the cross-sectional area of the columnar portion UHRmd as viewed from the stacking direction of the stacked body LM.

In the above-described replacement processing, the stepped portion LSPd is supported by the columnar portions LHRg and LHRs, which are the lower structures of the columnar portions HRfd and HRsd, respectively. Thus, if the XY cross-sectional area of the columnar portions LHRg and LHRs has a desired value, the columnar portions UHRmd and UHRsd, which are the upper structures, may have a different XY cross-sectional area from the columnar portions LHRg and LHRs, as described above.

Furthermore, in the stepped portion LSPd, the number of layers of the stacked body LM is reduced, and subsidence of the stacked body LM is relatively less likely to occur. Thus, in the case where the XY cross-sectional area of the upper and lower structures is made different, it is possible to make the XY cross-sectional area of the columnar portion UHRmd smaller than that of the columnar portion LHRg, for example, as described above. This configuration makes it possible to suppress contact with the contact CC further in the upper structure of the columnar portion HRfd.

According to the semiconductor storage device 2 of the first modification, other effects similar to those of the semiconductor storage device 1 of the embodiment described above are achieved.

Note that in the above-mentioned first modification, the columnar portion HRsd is arranged at a position adjacent to the plate-like contact LI in the region on the lower layer side except for the uppermost layer side of the stepped portion LSPd. However, the columnar portion HRfd may also be arranged at a position adjacent to the plate-like contact LI, and the plurality of columnar portions HRfd may be distributed and arranged over the entire area of the stepped portion LSPd except for the uppermost layer side.

The columnar portion UHRmd, which is the upper structure of the columnar portion HRfd, has a reduced diameter, for example, even with such an arrangement, contact with the plate-like contact LI can be suppressed. In other words, the diameter of the columnar portion UHRmd can be adjusted to avoid contact with the plate-like contact LI.

### SECOND MODIFICATION

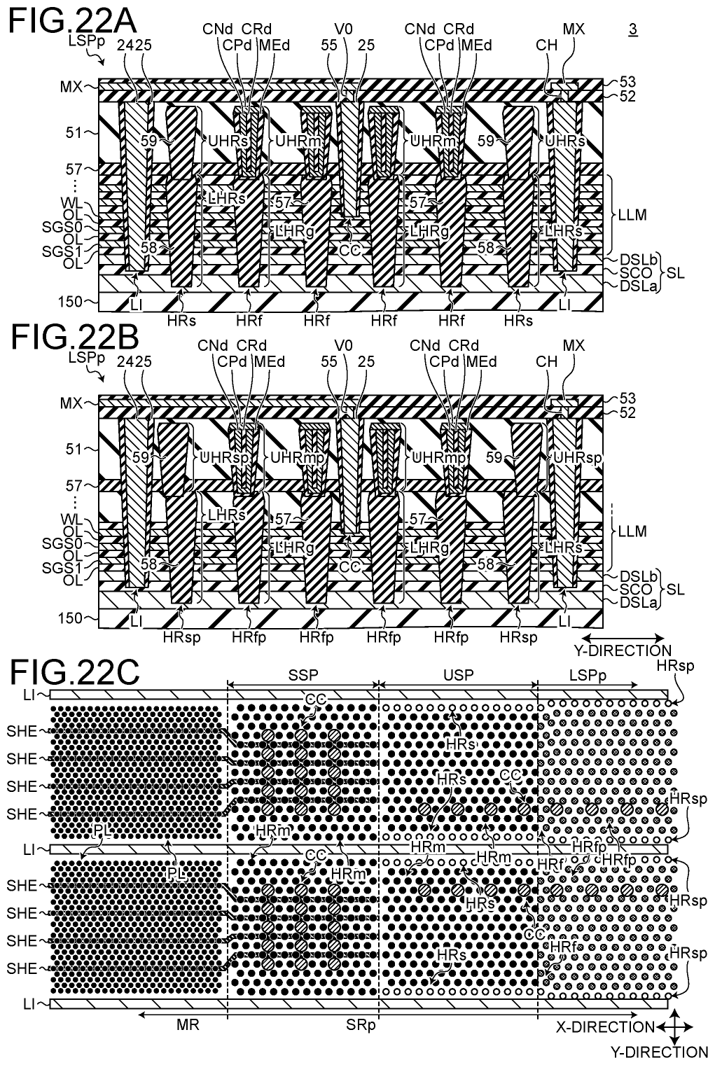

A semiconductor storage device 3 according to a second modification of the embodiment is now described with reference to FIGS. 22A to 22C. The semiconductor storage device 3 of the second modification differs from the above-described embodiment in that, in place of the above-described columnar portions HRf, the semiconductor storage device 3 includes columnar portions HRfp whose upper and lower structures have different pitches.

Note that in the following drawings, components identical to those in the above-described embodiments are denoted by identical reference numerals, and their descriptions may be omitted.

FIGS. 22A to 22C are diagrams illustrating an exemplary configuration of the semiconductor storage device 3 according to the second modification of the embodiment.

More specifically, FIG. 22A is a cross-sectional view along the Y-direction illustrating an exemplary configuration of the uppermost layer side of the stepped portion LSPp, and FIG. 22B is a cross-sectional view along the Y-direction illustrating an exemplary configuration of the columnar portion HRfp. In FIGS. 22A and 22B, the structures below the insulating layer 150 and above the insulating layer 53 are omitted.

FIG. 22C is an XY cross-sectional view of a partial region of the stacked body LM at the height position of the selection gate line SGD.

The semiconductor storage device 3 of the second modification has a schematic configuration similar to the semiconductor storage device 1 of the embodiment illustrated in FIG. 1 described above. In addition, the semiconductor storage device 3 has a configuration similar to that of the semiconductor storage device 1 of the above-described embodiment in the memory region MR and the stepped portions SSP and USP.

As illustrated in FIGS. 22A to 22C, in a step region SRp of the semiconductor storage device 3, in addition to the above-mentioned stepped portions USP and SSP, the stepped portion LSPp in which the word lines WL and the selection gate lines SGS belonging to the stacked body LLM are processed into a step shape is included. In the stepped portion LSPp, columnar portions HRf, HRs, HRfp, and HRsp are arranged.

The plurality of columnar portions HRf is arranged in a partial region near the top layer of the stepped portion LSPp. The plurality of columnar portions HRs is arranged at a position adjacent to the plate-like contact LI to correspond to the region where the columnar portions HRf are arranged in the X-direction.

In the stepped portion LSPp, the multiple columnar portions HRfp and HRsp are arranged in a region lower than the region where the columnar portions HRf and HRs are arranged. The plurality of columnar portions HRfp is arranged in a distributed manner in the lower region of the stepped portion LSPp, and the plurality of columnar portions HRsp is arranged at a position adjacent to the plate-like contact LI in the same level lower region of the stepped portion LSPp.

Each of the columnar portion HRfp includes the columnar portion LHRg as a lower structure and includes a columnar portion UHRmp extending in the stacking direction at the height position of the stacked body ULM as an upper structure. The columnar portion UHRmp includes the dummy layers MEd, CNd, and CRd in order from the outer circumferential side, for example, like the columnar portion UHRm of the above-described embodiment. The columnar portion UHRmp may include the dummy layer CPd.

Each of the columnar portion HRsp includes the columnar portion LHRs as a lower structure and includes a columnar portion UHRsp extending in the stacking direction at the height position of the stacked body ULM as an upper structure. The columnar portion UHRsp has, for example, a single-substance structure of the insulating layer 59, similar to the columnar portion UHRs of the above-described embodiment.

Similar to the columnar portions LHRg and LHRS, each of the columnar portions UHRmp and UHRsp has a circular, elliptical, or oval shape as the cross-sectional shape in the direction along the XY plane and has a tapered shape in which the diameter and cross-sectional area decrease from the upper end toward the lower end, or alternatively has a bowing shape in which the diameter and cross-sectional area are maximum between the upper end and the lower end.

In this regard, the pitches between the columnar portions UHRmp, between the columnar portions UHRsp, and between the columnar portions UHRmp and UHRsp differ from the pitches between the columnar portions LHRg, between the columnar portions LHRs, and between the columnar portions LHRg and LHRs, provided in the columnar portions HRfp and HRsp. More specifically, the pitches between the columnar portions UHRmp, between the columnar portions UHRsp, and between the columnar portions UHRmp and UHRsp are, for example, larger than the pitches between the columnar portions LHRg, between the columnar portions LHRs, and between the columnar portions LHRg and LHRs.

In this case, the central axes of the columnar portion UHRmp and the corresponding columnar portion LHRg and the central axes of the columnar portion UHRsp and the corresponding columnar portion LHRs do not coincide when viewed from the stacking direction of the stacked body LM. Even in this case, the pair of columnar portions UHRmp and LHRg and the pair of columnar portions UHRsp and LHRs can be arranged at positions that generally overlap in the stacking direction.

However, the columnar portion UHRmp and the columnar portion LHRg, or the columnar portion UHRsp and the columnar portion LHRs do not have to be connected, and the upper and lower structures thereof do not have to have a one-to-one correspondence.

Moreover, even in the case where the columnar portion HRfp is arranged in the stepped portion LSPp, as described above, the columnar portion HRf is arranged on the uppermost layer side of the stepped portion LSPp, that is, near the boundary with the stepped portion USP so that the columnar portions HRm and HRf, whose upper structure pitches are substantially equal, are adjacent to each other. This arrangement makes it possible to improve the processing accuracy of the columnar portion HRm arranged in the stepped portion USP at the boundary portion with the stepped portion LSPp.

According to the semiconductor storage device 3 of the second modification, each of the plurality of columnar portions HRfp includes the columnar portion LHRg and the columnar portion UHRmp. The columnar portion LHRg is a single-substance of the insulating layer 57 extending in the stacking direction on the lower layer side of the stacked body LM, and the columnar portion UHRmp is arranged at a height position on the upper layer side of the stacked body LM corresponding to the columnar part LHRg. In addition, the pitch between the columnar portions LHRg as viewed from the stacking direction of the stacked body LM is different from the pitch between the columnar portions UHRmp as viewed from the stacking direction of the stacked body LM.

In the above-described replacement processing, the stepped portion LSPp is supported by the columnar portions LHRg and LHRs, which are the lower structures of the columnar portions HRfp and HRsp, respectively. Thus, if the pitches of the columnar portions LHRg and LHRs have a desired interval, the columnar portions UHRfp and UHRsp, which are the upper structures, may have different pitches from the columnar portions LHRg and LHRs, respectively, as described above. This arrangement makes it possible to improve the degree of freedom in arranging the columnar portions UHRfp and UHRsp.

According to the semiconductor storage device 3 of the second modification, the pitch between the columnar portions UHRfp viewed from the stacking direction of the stacked body LM is larger than the pitch between the columnar portions LHRg viewed from the stacking direction of the stacked body LM. This arrangement further suppresses contact between the columnar portion UHRfp and the contact CC.

According to the semiconductor storage device 3 of the second modification, other effects similar to those of the semiconductor storage device 1 of the embodiment described above are achieved.

### THIRD MODIFICATION

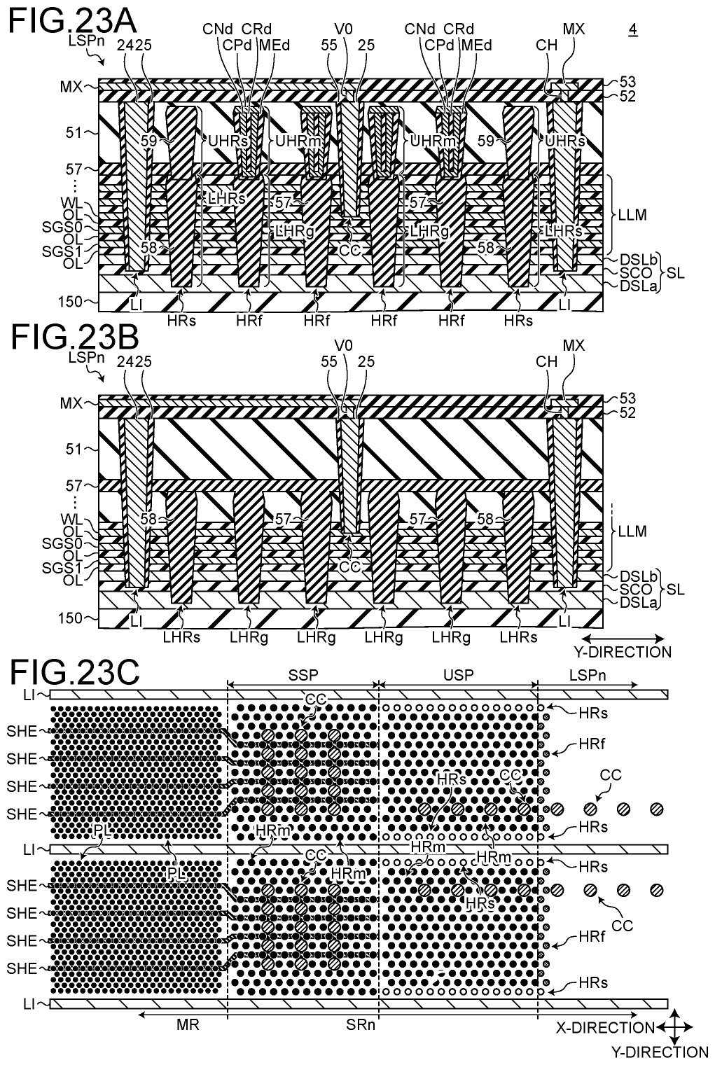

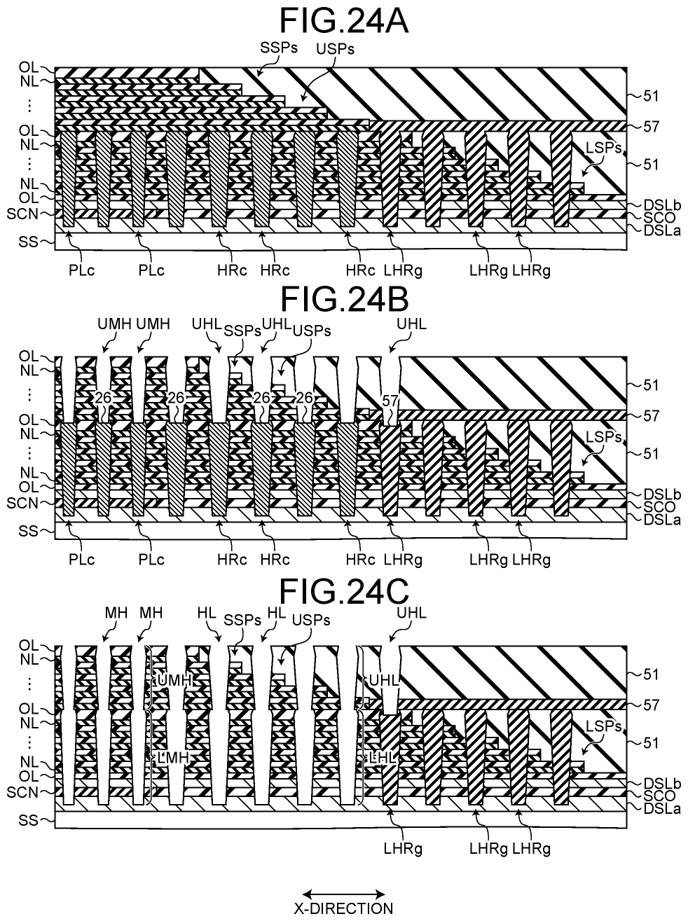

A semiconductor storage device 4 according to a third modification of the embodiment is now described with reference to FIGS. 23A to 24C. The semiconductor storage device 4 of the third modification differs from the above-described embodiment in that it includes a columnar portion LHRg that does not have an upper structure in place of the above-described columnar portion HRf.

Note that in the following drawings, components identical to those in the above-described embodiments are denoted by identical reference numerals, and their descriptions may be omitted.

FIGS. 23A to 23C are diagrams illustrating an exemplary configuration of the semiconductor storage device 4 according to the third modification of the embodiment.

More specifically, FIG. 23A is a cross-sectional view along the Y-direction illustrating an exemplary configuration of the uppermost layer side of a stepped portion LSPn, and FIG. 23B is a cross-sectional view along the Y-direction illustrating an exemplary configuration of the columnar portion LHRg. In FIGS. 23A and 23B, the structures below the insulating layer 150 and above the insulating layer 53 are omitted.

FIG. 23C is an XY cross-sectional view of a partial region of the stacked body LM at the height position of the selection gate line SGD.

The semiconductor storage device 4 of the third modification has a schematic configuration similar to that of the semiconductor storage device 1 of the embodiment illustrated in FIG. 1 described above. In addition, the semiconductor storage device 4 has a configuration similar to that of the semiconductor storage device 1 of the above-described embodiment in the memory region MR and the stepped portions SSP and USP.

As illustrated in FIGS. 23A to 23C, in a step region SRn of the semiconductor storage device 4, in addition to the above-mentioned stepped portions USP and SSP, the stepped portion LSPn in which the word lines WL and the selection gate lines SGS belonging to the stacked body LLM are processed into a step shape is included. In the stepped portion LSPn, columnar portions HRf and HRs, and columnar portions LHRg and LHRs having no upper structure are arranged.

The plurality of columnar portions HRf is arranged in a partial region of the stepped portion LSPn near the top layer. The plurality of columnar portions HRs is arranged at a position adjacent to the plate-like contact LI to correspond to the region where the columnar portions HRf are arranged in the X-direction.

In the stepped portion LSPn, the plurality of columnar portions LHRg that does not have an upper structure is distributed and arranged in a lower region of the stepped portion LSPn than the region where the columnar portions HRf and HRs are arranged.

In this regard, each of the columnar portions LHRg has a configuration similar to that of the columnar portion LHRg that is the lower structure of the columnar portion HRf of the above-described embodiment. However, unlike the columnar portion HRf of the above-described embodiment, each of the columnar portions LHRg does not have an upper structure extending in the stacking direction at a height position of the stacked body ULM.

Further, the columnar portion LHRg with no upper structure in the third modification has a single-substance structure of the insulating layer 57, and has an upper end portion at a height position of the upper surface of the stacked body LLM. In other words, in the semiconductor storage device 4 of the third modification, the columnar portion LHRg, which is arranged in the lower layer side region excluding the uppermost layer side of the stepped portion LSPn, has its upper end located at a height corresponding to the bottom surface of the stacked body ULM.

Furthermore, in the stepped portion LSPn, the plurality of columnar portions LHRs with no upper structure is arranged adjacent to the plate-like contact LI in a lower region of the stepped portion LSPn than the region where the columnar portions HRf and HRs are arranged.

In this regard, each of the columnar portions LHRs has a structure similar to that of the columnar portion LHRs which is the lower structure of the columnar portion HRs of the above-described embodiment, but unlike the columnar portion HRs of the above-described embodiment, each of the columnar portions LHRs does not have an upper structure extending in the stacking direction at a height position of the stacked body ULM.

In other words, the columnar portion LHRs with no upper structure of the third modification has a single-substance structure of the insulating layer 58 and an upper end portion at a height position of the upper surface of the stacked body LLM.

FIGS. 24A to 24C are cross-sectional views along the X-direction illustrating a part of the procedure of a method of manufacturing the semiconductor storage device 4 according to the third modification of the embodiment.

In the semiconductor storage device 4 of the third modification as well, for example, similar to the semiconductor storage device 1 of the embodiment described above, the processing steps illustrated in FIGS. 4A to 9B can be performed.

FIG. 24A, similar to FIG. 9B described above, illustrates the case where the stepped portions LSPs, the pillar PLC, and the columnar portions HRc and LHRg are formed in the stacked body LLMs that will later become the lower structure of the stacked body LM. In addition, FIG. 24A also illustrates the case where the stepped portions USPs and SSPs formed in the stacked body ULMs, which will later become the upper structure of the stacked body LM, are covered with an insulating layer 51. Moreover, although not illustrated, by this point, the plurality of columnar portions LHRs may have already been formed in the stepped portions USPs and LSPs, adjacent to the region where the plate-like contact LI will be formed later.

As illustrated in FIG. 24B, for example, the plurality of memory holes UMH and the plurality of holes UHL extending in the stacking direction at the height position of the stacked body ULMs are formed at once. The memory hole UMH penetrates the stacked body ULMs and reaches the upper end of the pillar PLC. The hole UHL penetrates the insulating layer 51 and the stacked body ULMs and reaches the upper end of the columnar portion HRC or the columnar portion LHRg. The hole UHL may reach the upper end of the columnar portion LHRs in addition to the columnar portion LHRg in the stepped portion USPs. In this case, unlike the above-described embodiment, the hole UHL is not formed at a position that overlaps the lower layer side of the stepped portion LSPs in the stacking direction, except for the top layer side of the stepped portion LSPs.

As illustrated in FIG. 24C, the sacrificial layer 26 filled in the pillars PLC and the columnar portions HRC and exposed at the bottoms of the plurality of memory holes UMH and the plurality of holes UHL through them is removed by ashing using oxygen plasma or the like. As a result, the plurality of memory holes MH and the plurality of holes HL are formed. Some of the holes UHL whose lower ends are connected to the columnar portions LHRg and LHRs remain as they are.

Then, similar to the above-described embodiment, the insulating layer 59 is filled in the hole UHL or the like remaining in the stepped portion USPs, and the plurality of columnar portions HRs is formed in the region of the stepped portion USPs that will be adjacent to the plate-like contact LI later.

Further, by forming the multilayer insulating layer MEb, the semiconductor layer CNb, and the insulating layer CRb in the memory hole MH, in the hole HL of the stepped portions USPs and SSPs, and in the hole UHL in the uppermost region of the stepped portion LSPs, the pillar PL and columnar portions HRm and HRf are formed. In this case, the columnar portion HRf is formed in a part of the uppermost layer side of the stepped portion LSPs.

After that, similar processing to the above-described embodiment is performed, and the semiconductor storage device 4 of the third modification is produced.

According to the semiconductor storage device 4 of the third modification, each of the plurality of columnar portions LHRg having no upper structure is a single-substance of the insulating layer 57 having its upper end at a height position corresponding to the bottom surface on the upper layer side of the stacked body LM.

In the above-mentioned replacement processing, the stepped portion LSPn is supported exclusively by the columnar portion LHRg arranged at the height position of the stacked body LLMs. Thus, it is not necessary to have an upper structure arranged at a height position of the stacked body ULM corresponding to the columnar portion LHRg arranged in the stepped portion LSPn.

Further, in the stepped portion LSPn, the columnar portion LHRg does not have an upper structure, so contact with the contact CC is further suppressed.

According to the semiconductor storage device 4 of the third modification, the plurality of columnar portions HRf is arranged between the plurality of columnar portions HRm and LHRg. As a result, upon forming the hole UHL that will later become the columnar portion HRm in the stepped portion USPs, it is possible to suppress opening defects or the like of the hole UHL in the region adjacent to the stepped portion LSPs, improving the processing accuracy of the columnar portion HRm.

### OTHER MODIFICATIONS

In the embodiment and first to third modifications described above, the step regions SR, SRd, SRp, and SRn are arranged at both ends of the stacked body LM in the X-direction. However, such a step region may be arranged at the middle of the stacked body as viewed from the stacking direction by digging down the middle of the stacked body in a stepwise manner. The configurations of the above-described any one of embodiment and first to third modifications can also be applied to such step regions.

Further, in the embodiment and first to third modifications described above, the pillar PL is connected to the source line SL on the side surface of the channel layer CN, but the embodiment is not limited to these examples. For example, the pillar may be configured such that the memory layer at the bottom of the pillar is removed and the lower end of the channel layer is connected to the source line.

Furthermore, in the embodiment and first to third modifications described above, the stacked body LM has a two-tier structure including the two stacked bodies LLM and ULM. However, the number of tiers of the stacked body may be three or more tiers. In this case, a columnar portion having the structure of any one of the columnar portions HRf, HRfd, HRfp, and LHRg in the embodiment and first to third modifications described above is arranged in the one-tier and two-tier. From three-tier onwards, it is possible to stack columnar portions with a configuration similar to the columnar portion UHRm.

Furthermore, in the embodiment and first to third modifications described above, the peripheral circuit CBA is arranged above the stacked body LM. However, the peripheral circuit may be placed below the stacked body or on the same level as the stacked body.

In the case where the peripheral circuit is arranged below the stacked body, it is possible to form the source line and the stacked body, for example, on an insulating layer of a semiconductor substrate having the peripheral circuit covered with the insulating layer. In the case where the peripheral circuit is arranged on the same level as the stacked body, it is possible to form the stacked body at a different position from the peripheral circuit on the semiconductor substrate where the peripheral circuit is formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a stacked body including a plurality of conductive layers stacked apart from each other, the plurality of conductive layers being processed into a step shape in a stepped portion;
a first pillar that extends in a stacking direction of the stacked body in the stacked body different from the stepped portion and forms a memory cell at each intersection portion with at least a part of the plurality of conductive layers; and
a plurality of second pillars that extends in the stacking direction in the stepped portion,
wherein
the plurality of second pillars each includes:
a first sub-pillar that is a single substance of a first insulating layer extending in the stacking direction in a lower layer side of the stacked body; and
a second sub-pillar arranged at a height position in an upper layer side of the stacked body to correspond to the first sub-pillar, and
the second sub-pillar includes:
a semiconductor layer extending in the stacking direction at the height position in the upper layer side of the stacked body;
a second insulating layer covering a sidewall of the semiconductor layer;
a third insulating layer covering a sidewall of the second insulating layer; and
a fourth insulating layer that includes a different material from the second and third insulating layers and is interposed between the second and third insulating layers.

2. The semiconductor storage device according to claim 1, further comprising:
a plurality of third pillars that extends in the stacking direction in the stepped portion at a position overlapping in the staking direction with a portion where upper-side conductive layers of the plurality of conductive layers are processed into a step shape,
wherein
the plurality of third pillars each includes:
the semiconductor layer that extends in the stacking direction from the upper layer side to the lower layer side of the stacked body;
the second insulating layer covering the sidewall of the semiconductor layer;
the third insulating layer covering the sidewall of the second insulating layer; and
the fourth insulating layer interposed between the second and third insulating layers.

3. The semiconductor storage device according to claim 2, further comprising:
a plurality of fourth pillars that extends in the stacking direction in the stepped portion at a position overlapping in the stacking direction with a portion where lower-side conductive layers of the plurality of conductive layers are processed into a step shape,
wherein
the plurality of fourth pillars each is a single substance of the first insulating layer having an upper end portion at a position corresponding to a bottom surface of the upper layer side of the stacked body, and
the plurality of second pillars is arranged between the plurality of third pillars and the plurality of fourth pillars.

4. The semiconductor storage device according to claim 3, further comprising:
a plate-like portion that extends in the stacking direction and a first direction intersecting the stacking direction and divides the stacked body in a second direction intersecting both directions of the stacking direction and the first direction; and
a plurality of fifth pillars arrayed in the first direction adjacently to the plate-like portion on both sides in the second direction of the plate-like portion at a position overlapping in the stacking direction with a portion where the upper-side conductive layers are processed into the step shape,
wherein
the plurality of fifth pillars each includes:
a fifth insulating layer that extends in the stacking direction in the lower layer side and the upper layer side of the stacked body.

5. The semiconductor storage device according to claim 4, further comprising:
a separation layer that penetrates an uppermost conductive layer among the plurality of conductive layers or penetrates the uppermost conductive layer and at least one conductive layer of the plurality of conductive layers continuous with the uppermost conductive layer in the stacking direction, extends in the first direction, and selectively separates one or more conductive layers of the plurality of conductive layers including the uppermost conductive layer in the second direction,
wherein
the plurality of third pillars is distributed and arranged, including a position adjacent to the plate-like portion in a region overlapping in the stacking direction with a portion where the one or more conductive layers are processed into a step shape.

6. The semiconductor storage device according to claim 5, wherein
the plurality of fifth pillars is arranged adjacently to the plate-like portion on both sides in the second direction of the plate-like portion, such that an arrangement of the plurality of fifth pillars is local within a region overlapping in the stacking direction with the portion where the upper-side conductive layers are processed into the step shape among regions overlapping in the stacking direction with the portions where the upper-side and lower-side conductive layers are processed into the step shape respectively and the region overlapping in the stacking direction with the portion where the one or more conductive layers are processed into the step shape.

7. The semiconductor storage device according to claim 2, wherein
the plurality of second pillars is distributed and arranged in a region overlapping in the stacking direction with a portion where lower-side conductive layers of the plurality of conductive layers are processed into a step shape.

8. The semiconductor storage device according to claim 7, wherein
a maximum cross-sectional area of the first sub-pillar is larger than a maximum cross-sectional area of the second sub-pillar, as viewed from the stacking direction.

9. The semiconductor storage device according to claim 7, wherein
a pitch between first sub-pillars included in the plurality of second pillars is different from a pitch between second sub-pillars included in the plurality of second pillars in correspondence with the first sub-pillars, as viewed from the stacking direction.

10. The semiconductor storage device according to claim 9, wherein
the pitch between the second sub-pillars is larger than the pitch between the first sub-pillars.

11. The semiconductor storage device according to claim 7, further comprising:
a plate-like portion that extends in the stacking direction and a first direction intersecting the stacking direction and divides the stacked body in a second direction intersecting both directions of the stacking direction and the first direction; and
a plurality of fifth pillars arrayed in the first direction adjacently to the plate-like portion on both sides in the second direction of the plate-like portion in the stepped portion,
wherein
the plurality of fifth pillars each includes:
a fifth insulating layer that extends in the stacking direction in the lower layer side of the stacked body and at the height position in the upper layer side of the stacked body.

12. The semiconductor storage device according to claim 11, further comprising:
a separation layer that penetrates an uppermost conductive layer among the plurality of conductive layers or penetrates the uppermost conductive layer and at least one conductive layer of the plurality of conductive layers continuous with the uppermost conductive layer in the stacking direction, extends in the first direction, and selectively separates one or more conductive layers of the plurality of conductive layers including the uppermost conductive layer in the second direction,
wherein
the plurality of third pillars is distributed and arranged, including a position adjacent to the plate-like portion in a region overlapping in the stacking direction with a portion where the one or more conductive layers are processed into a step shape.

13. The semiconductor storage device according to claim 12, wherein
the plurality of fifth pillars is arranged adjacently to the plate-like portion on both sides in the second direction of the plate-like portion, such that an arrangement of the plurality of fifth pillars is local within regions overlapping in the stacking direction with the portions where the upper-side and lower-side conductive layers are processed into the step shape respectively among the regions overlapping in the stacking direction with the portions where the upper-side and lower-side conductive layers are processed into the step shape respectively and the region overlapping in the stacking direction with the portion where the one or more conductive layers are processed into the step shape.

14. The semiconductor storage device according to claim 1, wherein
the stepped portion is covered with a sixth insulating layer that reaches a height position of an upper surface of the stacked body, and
the first insulating layer is further disposed in the sixth insulating layer at a height position corresponding to a bottom surface of the upper layer side of the stacked body to intersect with the plurality of second pillars.

15. A semiconductor storage device comprising:
a first stacked body including a plurality of first conductive layers stacked apart from each other, the plurality of first conductive layers being processed into a step shape in a first stepped portion;
a second stacked body including a plurality of second conductive layers stacked apart from each other, the second stacked body being arranged above the first stacked body and the plurality of second conductive layers being processed into a step shape in a second stepped portion to be continuous to the first stepped portion;
a first pillar that extends in a stacking direction of the first and second stacked bodies in the first and second stacked bodies different from the first and second stepped portions and forms a memory cell at each intersection portion with at least a part of the plurality of first and second conductive layers;
a plurality of second pillars that extends in the stacking direction at a first position overlapping in the stacking direction with the first stepped portion; and
a plurality of third pillars that extends in the stacking direction at a second position overlapping in the stacking direction with the second stepped portion,
wherein
the plurality of second pillars each includes:
a first sub-pillar that is a single substance of a first insulating layer extending in the stacking direction in the first stacked body; and
a second sub-pillar arranged at a height position of the second stacked body to correspond to the first sub-pillar,
the second sub-pillar includes:
a semiconductor layer that extends in the stacking direction at the height position of the second stacked body;
a second insulating layer covering a sidewall of the semiconductor layer;
a third insulating layer covering a sidewall of the second insulating layer; and
a fourth insulating layer that includes a different material from the second and third insulating layers and is interposed between the second and third insulating layers, and
the plurality of third pillars each includes:
the semiconductor layer that extends in the stacking direction in the first and second stacked bodies;
the second insulating layer covering the sidewall of the semiconductor layer;
the third insulating layer covering the sidewall of the second insulating layer; and
the fourth insulating layer interposed between the second and third insulating layers.

16. The semiconductor storage device according to claim 15, further comprising:
a plurality of fourth pillars that extends in the stacking direction at a third position overlapping in the stacking direction with the first stepped portion, wherein
the plurality of fourth pillars each is a single substance of the first insulating layer having an upper end portion at a height position of an upper surface of the first stacked body, and
the plurality of second pillars is arranged between the plurality of third pillars and the plurality of fourth pillars.

17. The semiconductor storage device according to claim 16, further comprising:
a plate-like portion that extends in the stacking direction and a first direction intersecting the stacking direction and divides the first and second stacked bodies in a second direction intersecting both directions of the stacking direction and the first direction; and
a plurality of fifth pillars arrayed in the first direction adjacently to the plate-like portion on both sides in the second direction of the plate-like portion in the second stepped portion,
wherein
the plurality of fifth pillars each includes:
a fifth insulating layer that extends in the stacking direction in the first and second stacked bodies.

18. The semiconductor storage device according to claim 15, wherein
the plurality of second pillars is distributed and arranged in the first stepped portion.

19. The semiconductor storage device according to claim 18, further comprising:
a plate-like portion that extends in the stacking direction and a first direction intersecting the stacking direction and divides the first and second stacked bodies in a second direction intersecting both directions of the stacking direction and the first direction; and
a plurality of fifth pillars arrayed in the first direction adjacently to the plate-like portion on both sides in the second direction of the plate-like portion in the first stepped portion,
wherein
the plurality of fifth pillars each includes:
a fifth insulating layer that extends in the stacking direction at least in the first stacked body.

20. The semiconductor storage device according to claim 15, wherein
the first and second stepped portions are covered with a sixth insulating layer that reaches a height position of an upper surface of the second stacked body, and
the first insulating layer is further disposed in the sixth insulating layer at a height position corresponding to a bottom surface of the second stacked body to intersect with the plurality of second pillars.
